(19) United States
(12) Patent Application Publication
(10) Pub. No.: US 2025/0141415 A1
(43) Pub. Date: May 1, 2025

(54) METHODS AND APPARATUS TO DYNAMICALLY INCREASE AMPLIFIER SLEW RATES

(71) Applicant: Texas Instruments Incorporated, Dallas, TX (US)

(72) Inventors: Vivek Varier, Tucson, AZ (US); Srinivas K Pulijala, Tucson, AZ (US); Vadim V. Ivanov, Dallas, TX (US)

(21) Appl. No.: 18/789,103

(22) Filed: Jul. 30, 2024

Related U.S. Application Data
(60) Provisional application No. 63/546,622, filed on Oct. 31, 2023.

(51) Int. Cl. H03F 3/45

(52) U.S. Cl. CPC H03F 3/45183; H03F 2203/45248; H03F 2203/45314; H03F 2203/45336; H03F 2203/45344

(57) ABSTRACT

An example apparatus includes: a first transistor having a first terminal and a control terminal; a second transistor having a first terminal and a control terminal, the first terminal of the second transistor coupled to the first terminal of the first transistor; a third transistor having a first terminal and a control terminal; a fourth transistor having a first terminal and a control terminal, the first terminal of the fourth transistor coupled to the first terminal of the third transistor; feedback circuitry coupled to the first transistor, the second transistor, the third transistor and the fourth transistor; current source circuitry having a first terminal and a second terminal, the first terminal of the current source circuitry coupled to the feedback circuitry; slew assist circuitry coupled to the first transistor, the second transistor, the third transistor and the fourth transistor, the feedback circuitry and the current source circuitry.

### CROSS-REFERENCE TO RELATED APPLICATION

This patent application claims the benefit of and priority to U.S. Provisional Patent Application No. 63/546,622 filed Oct. 31, 2023, which is hereby incorporated herein by reference in its entirety.

### TECHNICAL FIELD

This description relates generally to amplifiers and, more particularly, to methods and apparatus to dynamically increase amplifier slew rates.

### BACKGROUND

As electronics continue to advance, systems need to be capable of safely operating at increasingly higher powers and higher speeds. In amplifier circuitry, increasingly complex circuitry handles higher output voltages, output currents, and operating speeds. Such circuitry allows the amplifier circuitry to safely support a wide range of operating conditions.

### SUMMARY

For methods and apparatus to dynamically increase amplifier slew rates, an example apparatus includes a first transistor having a first terminal and a control terminal; a second transistor having a first terminal and a control terminal, the first terminal of the second transistor coupled to the first terminal of the first transistor; a third transistor having a first terminal and a control terminal; a fourth transistor having a first terminal and a control terminal, the first terminal of the fourth transistor coupled to the first terminal of the third transistor; feedback circuitry coupled to the first transistor, the second transistor, the third transistor and the fourth transistor; current source circuitry having a first terminal and a second terminal, the first terminal of the current source circuitry coupled to the feedback circuitry; slew assist circuitry coupled to the first transistor, the second transistor, the third transistor and the fourth transistor, the feedback circuitry and the current source circuitry; and current mirror circuitry coupled to the slew assist circuitry. Other examples are described.

For methods and apparatus to dynamically increase amplifier slew rates, an example apparatus includes a first transistor having a first input; a second transistor having a second input; input transistor circuitry coupled to the first transistor and the second transistor, the input transistor circuitry having a first output and a second output; slew assist circuitry coupled to the first transistor, the second transistor, and the input transistor circuitry, the slew assist circuitry having a first output and a second output; and output stage circuitry coupled to the input transistor circuitry and slew assist circuitry, the output stage circuitry having an output where a slew rate of a voltage on the output is based on a voltage on the first output of the slew assist circuitry and a voltage on the second output of the slew assist circuitry. Other examples are described.

For methods and apparatus to dynamically increase amplifier slew rates, an example apparatus includes feedback circuitry; current source circuitry having a first terminal and a second terminal, the first terminal of the current source circuitry is coupled to the feedback circuitry; a first transistor having a first terminal, a second terminal, and a control terminal; a second transistor having a first terminal, a second terminal, and a control terminal; a third transistor a first terminal, a second terminal, and a control terminal, the first terminal of the third transistor coupled to the current source circuitry and the first transistor; a fourth transistor a first terminal, a second terminal, and a control terminal; a fifth transistor having a first terminal and a control terminal, the first terminal of the fifth transistor coupled to the third transistor and the fourth transistor, the control terminal of the fifth transistor coupled to the feedback circuitry, the first transistor, and the second transistor; a sixth transistor having a first terminal and a control terminal, the first terminal of the sixth transistor coupled to the first transistor and the second transistor, the control terminal of the sixth transistor coupled to the feedback circuitry, the third transistor, and the fourth transistor; and current mirror circuitry coupled to the second transistor and the fourth transistor. Other examples are described.

### BRIEF DESCRIPTION OF THE DRAWINGS

FIG. 1 is a diagram of example amplifier circuitry including example input stage circuitry and example output stage circuitry.

FIG. 2 is a block diagram of an example of the input stage circuitry of FIG. 1 including slew assist circuitry that dynamically increases a slew rate of the output stage circuitry of FIG. 1.

FIG. 3 is a schematic diagram of an example of the input stage circuitry of FIGS. 1 and 2.

FIG. 4 is a block diagram of another example of the input stage circuitry of FIGS. 1, 2, and 3 including clamp circuitry.

FIG. 5 is a schematic diagram of an example of the input stage circuitry of FIGS. 1, 2, 3, and 4, including an example of the clamp circuitry of FIG. 4.

FIG. 6 is a schematic diagram of another example of the input stage circuitry of FIGS. 1, 2, 3, 4, and 5, including another example of the clamp circuitry of FIGS. 4 and 5.

FIG. 7 is a flowchart representative of example operations that may be at least one of executed, instantiated, or performed using an example implementation of the input stage circuitry of FIGS. 1, 2, 3, 4, 5, and 6 to dynamically increase a skew rate of the amplifier circuitry of FIG. 1.

FIG. 8 is a timing diagram of example operations of the amplifier circuitry of FIG. 1.

FIG. 9 is another timing diagram of example operation of the amplifier circuitry of FIG. 1.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

As electronics continue to advance, systems need to be capable of safely operating at increasingly higher powers and higher speeds. In amplifier circuitry, increasingly complex circuitry handles higher output voltages, output currents, and operating speeds. Such circuitry allows the amplifier circuitry to safely support a wide range of operating conditions.

When amplifier circuitry supports dynamic range rail-to-rail output voltages, an output signal of the amplifier circuitry may have a voltage between a high-side supply voltage (e.g., supply voltage) and a low-side supply voltage (e.g., reference voltage). In such designs, the high-side supply voltage is referred to as a first rail and the low-side supply voltage is referred to as a second rail. In dynamic amplifier designs, one or both of the rails may dynamically change (also referred to as floating) responsive to changes in the system, such as changes in a common mode voltage or an input voltage. In high-voltage devices, the first and second supply voltages of the amplifier circuitry become increasingly farther apart. In 85-volt (V) systems, for example, the amplifier circuitry may generate an output voltage across a range of 85 volts. In some such systems, the amplifier circuitry is structured to have up to an 85-volt change at the output. Such relatively large changes at the output of the amplifier circuitry increase the time during which the amplifier circuitry is in a transient condition. A transient condition is an operating state occurring when the amplifier circuitry is transitioning from a first output voltage to a second output voltage. When in the transient condition, the output of the amplifier circuitry inaccurately reflects an input. An ideal amplifier instantaneously adjusts the output responsive to the input voltage. However, delays and settling times of amplifier circuitry result in durations of time during which the amplifier circuitry is operating in the transient condition.

A speed at which an amplifier circuitry adjusts an output in response to an input change is characterized as a slew rate. The slew rate is a measure of voltage per unit of time at which the amplifier circuitry can adjust the output (e.g., millivolts/second). Increasing the slew rate of the amplifier circuitry decreases the duration of transient operations, which increases the bandwidth of the amplifier circuitry.

Some amplifier circuitry includes high-voltage input switches, input transistor circuitry, feedback circuitry, and output stage circuitry. One method to increase the slew rate of amplifier circuitry is to increase the current of the signal path. The main signal path through the amplifier circuitry begins at the high-voltage switches, which receive first and second inputs of the amplifier circuitry. The high-voltage switches may be implemented using high-voltage transistors. The high-voltage switches control relatively low voltage transistors of the input transistor circuitry, which generate an intermediate signal path output using a tail current source, which represents the first and second inputs. In such designs the high-voltage switches protect transistors of the input transistor circuitry from high voltages of the first and second inputs.

During steady state operating conditions (e.g., no transient at the inputs of the amplifier circuitry), the output stage circuitry generates an output signal responsive to the intermediate signal path outputs. In some designs, the feedback circuitry generates a feedback current responsive to transients at the first and second inputs of the amplifier circuitry. The feedback circuitry uses the feedback current to pull down a control voltage, which increases the tail currents of the intermediate signal path outputs. During slew event conditions (e.g., a transient at the inputs of the amplifier circuitry), increasing the tails currents of the intermediate signal path outputs increases the slew rate of setting the output signal. However, increasing the tail currents of the intermediate signal path outputs increases the overshoot of the output of the amplifier circuitry, which increases a small signal settling time of the amplifier circuitry. Such an increase in the small signal settling time negates at least a portion of the increased slew rate. Also, as the transient at the inputs of the amplifier circuitry settles, the feedback circuitry allows the control voltage to settle which sets the tail current back to the steady state value. However, when the tail current transitions from the increased tail current to a steady state tail current, a delay in the transition between currents can result in a relatively high transconductance. Thus, such delay creates stability issues that further increase the settling time of the amplifier circuitry.

Examples described herein include methods and apparatus to dynamically increase amplifier slew rates using slew assist circuitry. In some described examples, the amplifier circuitry includes first current source circuitry, input transistor circuitry, feedback circuitry, slew assist circuitry, second current source circuitry, current mirror circuitry, driver circuitry, and power stage circuitry. The amplifier circuitry receives a first input signal at a first transistor and a second input signal at a second transistor. The first and second transistors cause the input transistor circuitry to generate intermediate signal path outputs based on values of the first and second input signals and a set current from the first current source circuitry. The driver circuitry generates high-side and low side control signals based on the intermediate signal path outputs. The power stage circuitry generates an output signal by using the high-side and low-side control signals to control a high-side and low-side transistor.

In the described examples, during steady state operating conditions (e.g., no transient at the inputs of the amplifier circuitry), the slew assist circuitry steers a slew assist current from the second current source circuitry to a common terminal, which supplies the common potential. During steady state operating conditions, the slew assist circuitry uses a cross-coupled pair of transistors that implement a cascode bias (e.g., one relatively large transistor cross coupled with a relatively small transistor) to further reduce current from the second current source from entering the main signal path. Such a method of control is referred to as minimum selector cascodes.

During slew event conditions (e.g., a transient at the inputs of the amplifier circuitry), the feedback circuitry generates a feedback current responsive to the transient. The feedback circuitry uses the feedback current to pull down a control voltage, which increases the slew assist current from the second current source circuitry. In some described examples, the current mirror circuitry sinks a mirror of the slew assist current to increase the speed at which the feedback circuitry pulls down the control voltage. Also, in some examples clamp circuitry prevents the current mirror circuitry from sinking the slew assist current during steady state conditions. During the slew event conditions, the slew assist circuitry turns on a first pair of transistors form a first current path, which supplies the increased slew assist current to the current mirror circuitry. Also, during the slew event conditions, the slew assist circuitry forms a second current path from a second pair of transistors to the common potential by turning on a transistor of cross-coupled cascode to steer non-ideal currents. In such operations, the transistor of the cross-coupled cascode reduces a supply of non-ideal current by the second pair of transistors.

The current mirror circuitry receives the slew assist current at one of a first or second output of the slew assist circuitry. The current mirror circuitry generates a first bias voltage responsive to currents at the first output of the slew assist circuitry and a second bias voltage responsive to currents at the second output of the slew assist circuitry. The power stage circuitry receives the first or second bias voltage from the current mirror circuitry. The first bias voltage causes the power stage circuitry to sink current from the low-side transistor by mirroring the slew assist current. Sinking current from the low-side transistor increases the slew rate of rising edges at the output of the amplifier circuitry. The second bias voltage causes the power stage circuitry to supply current to the high-side transistor by mirroring the slew assist current. Supplying current to the high-side transistor increases the slew rate of falling edges at the output of the amplifier circuitry.

Advantageously, supplying current to the high-side transistor increases the slew rate of the amplifier circuitry for generating falling edges on the output signal. Advantageously, sinking current from the low-side transistor increases the slew rate of the amplifier circuitry for generating rising edges on the output signal. Advantageously, the slew assist circuitry increases the slew rate of the amplifier circuitry without increasing the current of the intermediate signal path outputs. Advantageously, decreasing the currents of the intermediate signal path outputs decreases overshoot of the output signal of the amplifier circuitry, which decreases a small signal settling time of the output signal. Advantageously, as the amplifier circuitry recovers from slew event conditions, the slew assist circuitry uses a cascode bias and minimum selector control to steer non-ideal currents from the main signal path.

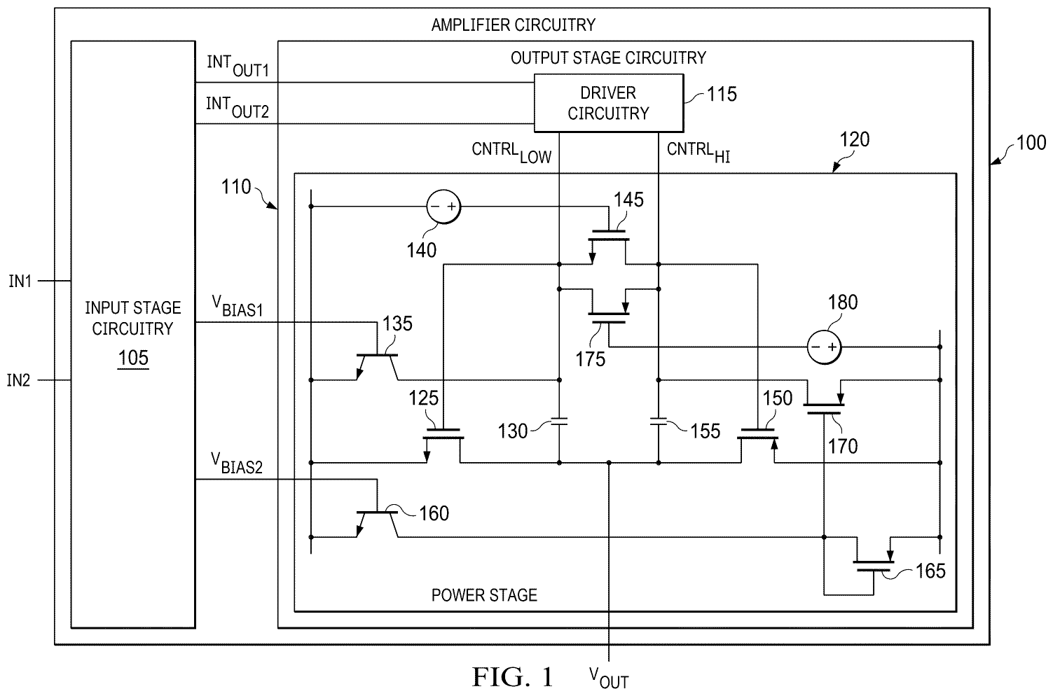

FIG. 1 is a diagram of example amplifier circuitry 100 including example input stage circuitry 105 and example output stage circuitry 110. In the example of FIG. 1, the output stage circuitry 110 includes driver circuitry 115 and power stage circuitry 120. The example power stage circuitry 120 of FIG. 1 includes a first example transistor 125, a first example capacitor 130, a second example transistor 135, first example voltage source circuitry 140, a third example transistor 145, a fourth example transistor 150, a second example capacitor 155, a fifth example transistor 160, a sixth example transistor 165, a seventh example transistor 170, an eighth example transistor 175, and second example voltage source circuitry 180.

The amplifier circuitry 100 has a first input terminal, a second input terminal, and an output terminal. The first and second input terminals are structured to be coupled to external circuitry, which supplies a first input (IN1) and a second input (IN2). In some examples, the first and second inputs represent a differential pair of input signals. Transients at the first and second inputs represent transitions in data of the differential pair of input signals. In such examples, when the inputs switch from one logic level (e.g., logic one, logic zero) to another, the amplifier circuitry 100 transitions an output voltage (V_{OUT}) at the output terminal. In the example of FIG. 1, the input stage circuitry 105 dynamically increases a slew rate of the transition of the output of the amplifier circuitry 100 in response to transients at the first and second inputs. Advantageously, increasing the slew rate decreases the response time of the amplifier circuitry 100.

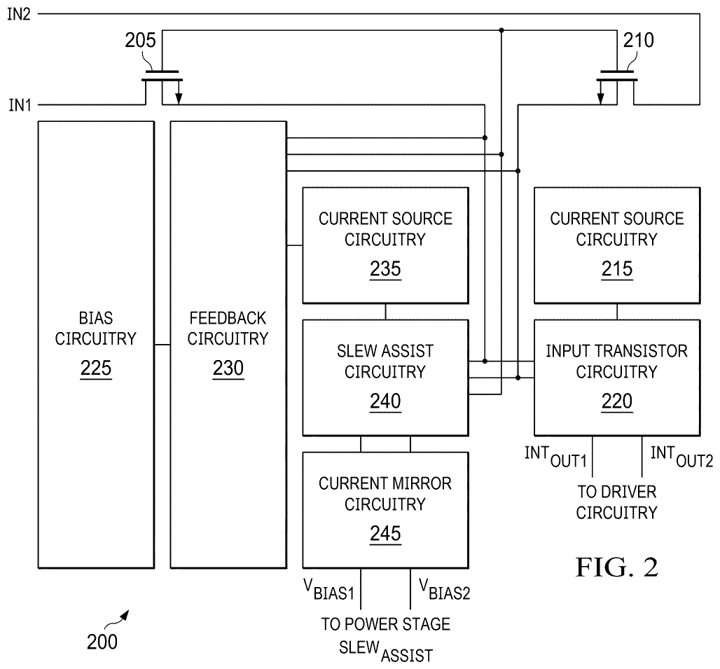

The input stage circuitry 105 has a first terminal, a second terminal, a third terminal, a fourth terminal, a fifth terminal, and a sixth terminal. The first and second terminals of the input stage circuitry 105 are structured to be coupled to external circuitry, which supplies the first and second inputs of the amplifier circuitry 100. The second, third, fourth, and fifth terminals of the input stage circuitry 105 are coupled to the output stage circuitry 110. Examples of the input stage circuitry 105 are illustrated and described in connection with FIGS. 2, 3, 4, 5, and 6, below.

The output stage circuitry 110 has a first terminal, a second terminal, a third terminal, a fourth terminal, and a fifth terminal. The first, second, third, and fourth terminals of the output stage circuitry 110 are coupled to the input stage circuitry 105. The fifth terminal of the output stage circuitry 110 is structured to be coupled to external circuitry. Such external circuitry is structured to receive the output of the amplifier circuitry 100.

The driver circuitry 115 has a first terminal, a second terminal, a third terminal, and a fourth terminal. The first and second terminals of the driver circuitry 115 are coupled to the input stage circuitry 105. The second and third terminals of the driver circuitry 115 are coupled to the power stage circuitry 120. In the example of FIG. 1, the driver circuitry 115 is structured as class AB driver circuitry, which linearly controls the power stage circuitry 120 based on signals from the input stage circuitry 105. In such examples, the driver circuitry 115 is structured to generate a high-side and low-side control signals to control conduction of the power stage circuitry 120 responsive to signals from the input stage circuitry 105.

The power stage circuitry 120 has a first terminal, a second terminal, a third terminal, a fourth terminal, and a fifth terminal. The first and second terminals of the power stage circuitry 120 are coupled to the input stage circuitry 105. The third and fourth terminals of the power stage circuitry 120 are coupled to the driver circuitry 115. The fifth terminal of the power stage circuitry 120 is structured to be coupled to external circuitry, which receives the output of the amplifier circuitry 100. In the example of FIG. 1, the power stage circuitry 120 is structured to generate the output of the amplifier circuitry 100 responsive to bias voltages from the input stage circuitry 105 and control signals from the driver circuitry 115. Alternatively, the power stage circuitry 120 may be modified to receive currents from the input stage circuitry 105.

The transistor 125 has a first terminal, a second terminal, and a control terminal. The first terminal of the transistor 125 is coupled to the capacitors 130, 155, the transistor 150, and the output terminal of the amplifier circuitry 100. The second terminal of the transistor 125 is coupled to the common terminal, which supplies a common potential (e.g., ground, AVSS, etc.). The control terminal of the transistor 125 is coupled to the driver circuitry 115, the capacitor 130, and the transistors 135, 145, 175. In some examples, the transistor 125 is referred to as a low-side field-effect transistor (FET). In such examples, the driver circuitry 115 controls the transistor 125 using a low-side control signal.

The capacitor 130 has a first terminal and a second terminal. The first terminal of the capacitor 130 is coupled to the driver circuitry 115 and the transistors 125, 145. The second terminal of the capacitor 130 is coupled to the transistors 125, 150, 175, the capacitor 155, and the output terminal of the amplifier circuitry 100. In the example of FIG. 1, the capacitor 130 represents a Miller capacitance between terminals of the transistor 125. In some examples, the capacitor 130 is illustrated or described as a non-ideal (e.g., parasitic) capacitance. In other examples, the capacitor 130 may not be illustrated.

The transistor 135 has a first terminal, a second terminal, and a control terminal. The first terminal of the transistor 135 is coupled to the driver circuitry 115, the transistors 125, 145, 175, and the capacitor 130. The second terminal of the transistor 135 is coupled to the common terminal, which supplies the common potential. The control terminal of the transistor 135 is coupled to the input stage circuitry 105, which supplies a second bias voltage (Bias2). In the example of FIG. 1, the transistor 135 is structured to sink current from the transistors 125, 145 and the capacitor 130. In such an example, the transistor 135 adjusts the slew rate of the transistor 125 by sinking current from the capacitor 130. Advantageously, adjusting the second bias voltage adjusts the slew rate of the transistor 125 by compensating the capacitor 130 with excess charge.

The voltage source circuitry 140 has a first terminal and a second terminal. The first terminal of the voltage source circuitry 140 is coupled to the transistor 145. The second terminal of the voltage source circuitry 140 is coupled to the common terminal, which supplies the common potential. In the example of FIG. 1, the voltage source circuitry 140 is structured as bias circuitry, which ensures the transistor 145 is in an operational state (e.g., conducting current). The transistor 145 has a first terminal, a second terminal, and a control terminal. The first terminal of the transistor 145 is coupled to the driver circuitry 115, the transistors 150, 170, 175, and the capacitor 155. The second terminal of the transistor 145 is coupled to the driver circuitry 115, the transistors 125, 135, 175, and the capacitor 130. The control terminal of the transistor 145 is coupled to the voltage source circuitry 140. In some examples, the transistor 145 is structured as common mode regulation circuitry, which regulates a common mode voltage (V_{CM}) of the transistors 125, 150. Alternatively, the voltage source circuitry 140 and the transistor 145 may be removed or replaced with alternative circuitry.

The transistor 150 has a first terminal, a second terminal, and a control terminal. The first terminal of the transistor 150 is coupled to a supply terminal, which supplies a supply voltage (VDD). The second terminal of the transistor 150 is coupled to the transistor 125, the capacitors 130, 155, and the output terminal of the amplifier circuitry 100. The control terminal of the transistor 150 is coupled to the driver circuitry 115, the transistors 145, 170, 175, and the capacitor 155. In some examples, the transistor 150 is referred to as a high-side field-effect transistor (FET). In such examples, the driver circuitry 115 controls the transistor 150 using a high-side control signal.

The capacitor 155 has a first terminal and a second terminal. The first terminal of the capacitor 155 is coupled to the transistors 125, 150, the capacitor 130, and the output terminal of the amplifier circuitry 100. The second terminal of the capacitor 155 is coupled to the driver circuitry 115 and the transistors 145, 150, 170, 175. In the example of FIG. 1, the capacitor 155 represents a Miller capacitance between terminals of the transistor 150. In some examples, the capacitor 155 is illustrated or described as a non-ideal (e.g., parasitic) capacitance. In other examples, the capacitor 130 may not be illustrated.

The transistor 160 has a first terminal, a second terminal, and a control terminal. The first terminal of the transistor 160 is coupled to the transistors 165, 170. The second terminal of the transistor 160 is coupled to the common terminal, which supplies the common potential. The control terminal of the transistor 160 is coupled to the input stage circuitry 105, which supplies a first bias voltage (Bias 1). In the example of FIG. 1, the transistor 160 is structured to sink current from the transistor 165 responsive to the first bias voltage.

The transistor 165 has a first terminal, a second terminal, and a control terminal. The first terminal of the transistor 165 is coupled to the supply terminal, which supplies the supply voltage. The second and control terminals of the transistor 165 are coupled to the transistors 160, 170. The transistor 170 has a first terminal, a second terminal, and a control terminal. The first terminal of the transistor 170 is coupled to the supply terminal, which supplies the supply voltage. The second terminal of the transistor 170 is coupled to the driver circuitry 115, the transistors 145, 150, 175, and the capacitor 155. The control terminal of the transistor 170 is coupled to the transistors 160, 165.

In the example of FIG. 1, the transistors 165, 170 are structured as current mirror circuitry, which mirrors the current being sunk by the transistor 160. Alternatively, the power stage circuitry 120 may be modified to remove or replace the transistors 165, 170 with alternative current mirror circuitry or current source circuitry. Advantageously, the transistor 170 supplies a current to the transistors 145, 150 and the capacitor 155 proportional to the current through the transistor 160. Advantageously, adjusting the first bias voltage adjusts the slew rate of the transistor 150 by compensating the capacitor 155 with excess charge.

The transistor 175 has a first terminal, a second terminal, and a control terminal. The first terminal of the transistor 175 is coupled to the driver circuitry 115, the transistors 125, 135, 145, and the capacitor 130. The second terminal of the transistor 175 is coupled to the driver circuitry 115, the transistors 145, 150, 170, and the capacitor 155. The control terminal of the transistor 175 is coupled to the voltage source circuitry 180. The voltage source circuitry 180 has a first terminal and a second terminal. The first terminal of the voltage source circuitry 180 is coupled to the supply terminal, which supplies the supply voltage. The second terminal of the voltage source circuitry 180 is coupled to the transistor 175.

In the example of FIG. 1, the transistors 125, 145 are n-channel metal-oxide semiconductor field-effect transistors (MOSFETs). Alternatively, the transistors 125, 145 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 1, the transistors 135, 160 are NPN BJTs. Alternatively, the transistors 135, 160 may be n-channel MOSFETs, n-channel FETs, n-channel IGBTs, n-channel JFETs or, with slight modifications, p-type equivalent devices. In the example of FIG. 1, the transistors 150, 165, 170, 175 are p-channel MOSFETs. Alternatively, the transistors 150, 165, 170, 175 may be p-channel FETs, p-channel IGBTs, p-channel JFETs, PNP BJTs, or, with slight modifications, N-type equivalent devices. The transistors 125, 135, 145, 150, 160, 165, 170, 175 may be depletion mode devices, drain-extended devices, enhancement mode devices, natural transistors or other type of device structure transistors. Furthermore, the transistors 125, 135, 145, 150, 160, 165, 170, 175 may be implemented in/over a silicon substrate (Si), a silicon carbide substrate (SiC), a gallium nitride substrate (GaN) or a gallium arsenide substrate (GaAs).

In example operation, the input stage circuitry 105 receives the first and second inputs from external circuitry. The input stage circuitry 105 generates first and second intermediate signal path outputs (INT_{OUT1}, INT_{OUT2}) responsive to the first and second inputs (IN1, IN2). The driver circuitry 115 generates the high-side and low-side control signals (CNTRL_{HI}, CNTRL_{LOW}) based on the first and second intermediate signal path outputs. The power stage circuitry 120 generates the output (V_{OUT}) of the amplifier circuitry 100 by using the high-side control signal to control the transistor 150 and the low-side control signal to control the transistor 125.

In such example operations, the input stage circuitry 105 generates the first and second bias voltages (V_{BIAS1}, V_{BIAS2}) responsive to determining a transient at the first and second inputs of the amplifier circuitry 100. The power stage circuitry 120 uses the first bias voltage to control the transistor 160. The transistors 165, 170 mirror the current through the transistor 160 to supply a current to the transistor 150, which compensates for excess charges of the capacitor 155. The power stage circuitry 120 uses the second bias voltage to control the transistor 135, which sinks a current from the transistor 125 and compensates for excess charges of the capacitor 130. Advantageously, the first and second bias voltages control a supply of current to or from the capacitors 130, 155, which adjusts the slew rate of the amplifier circuitry 100. Advantageously, supplying current to the transistor 150 increases the slew rate of falling edges at the output of the amplifier circuitry 100. Advantageously, sinking current from the transistor 125 increases the slew rate of rising edges at the output of the amplifier circuitry 100. Example operations of the input stage circuitry 105 to generate the intermediate signal path outputs and the bias voltages are described further below.

FIG. 2 is a block diagram of example input stage circuitry 200, which is an example of the input stage circuitry 105 of FIG. 1. In the example of FIG. 2, the input stage circuitry 200 includes a first transistor 205, a second transistor 210, first current source circuitry 215, input transistor circuitry 220, bias circuitry 225, feedback circuitry 230, second current source circuitry 235, slew assist circuitry 240, and current mirror circuitry 245. The example input stage circuitry 200 of FIG. 2 is structured to be coupled to external circuitry, which supplies a first and second input (IN1, IN2), and the output stage circuitry 110 of FIG. 1.

The input stage circuitry 200 has a first input terminal, a second input terminal, a first output terminal, a second output terminal, a third output terminal, and a fourth output terminal. The first input terminal of the input stage circuitry 200 is structured to be coupled to external circuitry, which supplies a first input (IN1). The second input terminal of the input stage circuitry 200 is structured to be coupled to external circuitry which supplies a second input (IN2). The first and second output terminals of the input stage circuitry 200 are structured to be coupled to the driver circuitry 115 of FIG. 1. The input stage circuitry 200 supplies first and second intermediate signal path outputs (INT_{OUT1}, INT_{OUT2}) to the driver circuitry 115 at the first and second output terminals. The third output terminal of the input stage circuitry 200 is structured to be coupled to the transistor 135 of FIG. 1, which receives a first bias voltage (V_{BIAS1}) from the input stage circuitry 200. The fourth output terminal of the input stage circuitry 200 is structured to be coupled to the transistor 160 of FIG. 1, which receives a second bias voltage (V_{BIAS2}) from the input stage circuitry 200.

The transistor 205 has a first terminal, a second terminal, and a control terminal. The first terminal of the transistor 205 is coupled to the first input terminal of the input stage circuitry 200, which supplies the first input (IN1). The second terminal of the transistor 205 is coupled to the input transistor circuitry 220, the slew feedback circuitry, and the slew assist circuitry 240. The control terminal of the transistor 205 is coupled to the transistor 210, the feedback circuitry 230, the slew assist circuitry 240, and may be coupled to common mode regulator circuitry, which regulates a common mode voltage (V_{CM}) of the input stage circuitry 200.

The transistor 210 has a first terminal, a second terminal, and a control terminal. The first terminal of the transistor 210 is coupled to the second input terminal of the input stage circuitry 200, which supplies the second input (IN2). The second terminal of the transistor 210 is coupled to the input transistor circuitry 220, the feedback circuitry 230, and the slew assist circuitry 240. The control terminal of the transistor 210 is coupled to the transistor 205, the feedback circuitry 230, the slew assist circuitry 240, and may be coupled to common mode regulator circuitry, which regulates the common mode voltage of the input stage circuitry 200.

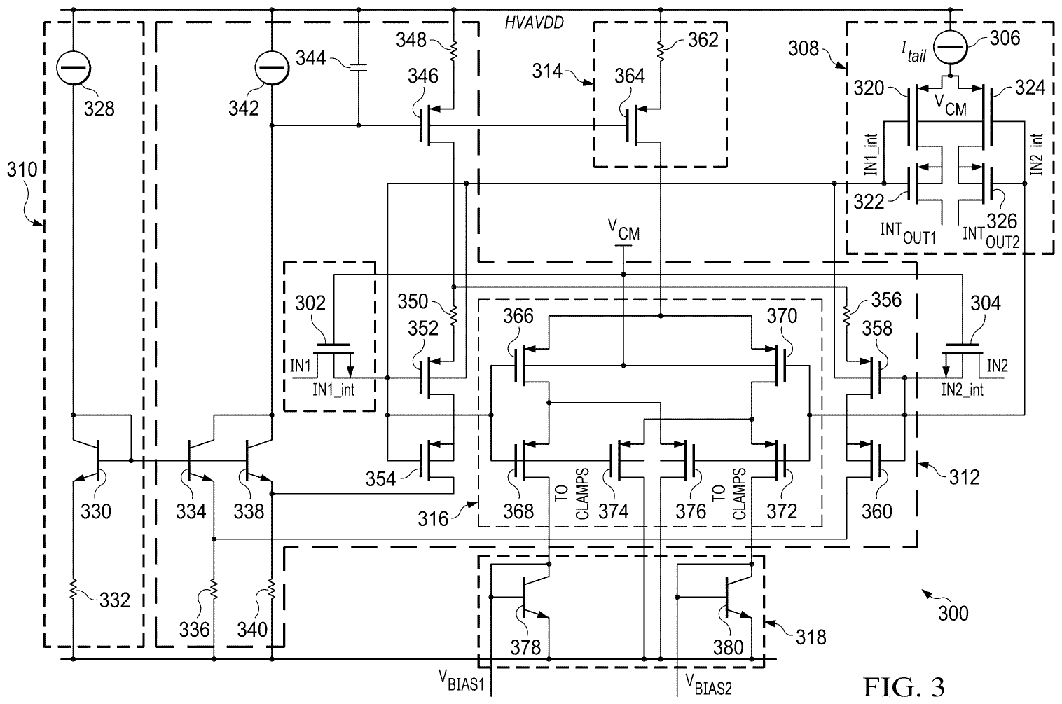

The current source circuitry 215 has a terminal coupled to the input transistor circuitry 220. An example of the current source circuitry 215 is illustrated and described in connection with FIGS. 3, 4, 5, and 6, below. In the example of FIG. 2, the current source circuitry 215 is structured to supply a fixed current (also referred to as a tail current). In such examples, the tail current has a magnitude that reduces small signal settling time by reducing overshoot caused by the high-side and low-side control signals.

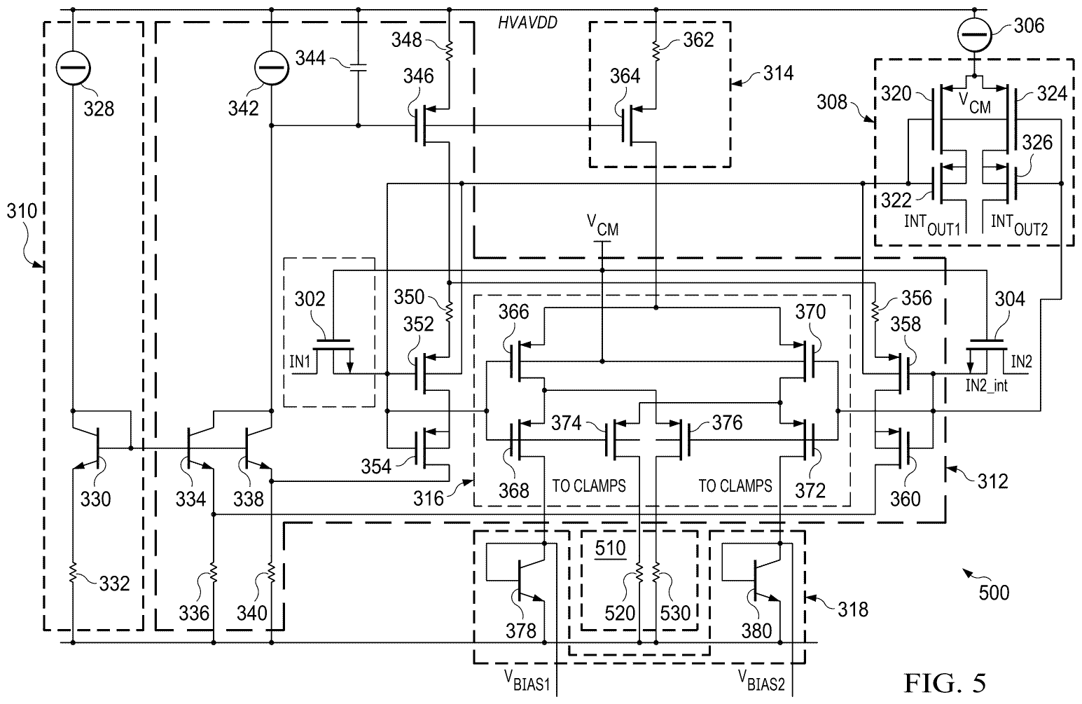

The input transistor circuitry 220 has a first terminal, a second terminal, a third terminal, a fourth terminal, and a fifth terminal. The first terminal of the input transistor circuitry 220 is coupled to the current source circuitry 215. The second terminal of the input transistor circuitry 220 is coupled to the transistor 205, the feedback circuitry 230, and the slew assist circuitry 240. The third terminal of the input transistor circuitry 220 is coupled to the transistor 210, the feedback circuitry 230, and the slew assist circuitry 240. The fourth and fifth terminals of the input transistor circuitry 220 is coupled to the first output terminal of the input stage circuitry 200, which supplies the first and second intermediate signal path outputs (INT_{OUT1}, INT_{OUT2}) to the driver circuitry 110. In the example of FIG. 2, the input transistor circuitry 220 generates the intermediate signal path outputs based on the first and second inputs of the input stage circuitry 200. An example of the input transistor circuitry 220 is illustrated and described in connection with FIGS. 3 and 5, below.

The bias circuitry 225 has a terminal coupled to the slew feedback circuitry. In the example of FIG. 2, the bias circuitry 225 is structured to bias the feedback circuitry 230. In such examples, the bias circuitry 225 ensures the feedback circuitry 230 is in an operational state despite steady state conditions. An example of the bias circuitry 225 is illustrated and described in connection with FIGS. 3, 5, and 6, below.

The feedback circuitry 230 has a first terminal, a second terminal, a third terminal, a fourth terminal, and a fifth terminal. The first terminal of the feedback circuitry 230 is coupled to the transistor 205, the input transistor circuitry 220, and the slew assist circuitry 240. The second terminal of the feedback circuitry 230 is coupled to the transistor 210, the input transistor circuitry 220, and the slew assist circuitry 240. The third terminal of the feedback circuitry 230 is coupled to the transistors 205, 210, the slew assist circuitry 240, and may be coupled to common mode regulator circuitry, which regulates the common mode voltage of the input stage circuitry 200. The fourth terminal of the feedback circuitry 230 is coupled to the bias circuitry 225. The fifth terminal of the feedback circuitry 230 is coupled to the current source circuitry 235. An example of the feedback circuitry 230 is illustrated and described in connection with FIGS. 3, 5, and 6, below.

The current source circuitry 235 has a first terminal and a second terminal. The first terminal of the current source circuitry 235 is coupled to the feedback circuitry 230. The second terminal of the current source circuitry 235 is coupled to the slew assist circuitry 240. In the example of FIG. 2, the current source circuitry 235 is structured to supply a slew assist current to the slew assist circuitry 240 based on the feedback circuitry 230. An example of the current source circuitry 235 is illustrated and described in connection with FIGS. 3, 5, and 6, below.

The slew assist circuitry 240 has a first terminal, a second terminal, a third terminal, a fourth terminal, a fifth terminal, and a sixth terminal. The first terminal of the slew assist circuitry 240 is coupled to the transistor 205, the input transistor circuitry 220, and the feedback circuitry 230. The second terminal of the slew assist circuitry 240 is coupled to the transistor 210, the input transistor circuitry 220, and the feedback circuitry 230. The third terminal of the slew assist circuitry 240 is coupled to the transistors 205, 210 and may be coupled to common mode regulator circuitry, which regulates the common mode voltage of the input stage circuitry 200. The fourth and fifth terminals of the slew assist circuitry 240 are coupled to the current mirror circuitry 245. An example of the slew assist circuitry 240 is illustrated and described in connection with FIGS. 3, 5, and 6, below.

The current mirror circuitry 245 has a first terminal, a second terminal, a third terminal, and a fourth terminal. The first and second terminals of the current mirror circuitry 245 are coupled to the slew assist circuitry 240. The third and fourth terminals of the current mirror circuitry 245 are coupled to the third and fourth output terminals of the input stage circuitry 200, which supply the first and second bias voltages (V_{BIAS1}, V_{BIAS2}) to the power stage circuitry 120 of FIG. 1, or more generally the output stage circuitry 110. In the example of FIG. 2, the current mirror circuitry 245 is structured to generate bias voltages that, when coupled to control terminals of transistors (e.g., the transistors 135, 160 of FIG. 1), mirror currents of the slew assist circuitry 240. Examples of the current mirror circuitry 245 are illustrated and described in FIGS. 3, 5, and 6, below.

In the example of FIG. 2, the transistors 205, 210 are n-channel MOSFETs. Alternatively, the transistors 205, 210 may be n-channel FETs, n-channel IGBTs, n-channel JFETs, NPN BJTs or, with slight modifications, p-type equivalent devices. The transistors 205, 210 may be depletion mode devices, drain-extended devices, enhancement mode devices, natural transistors or other types of device structure transistors. Furthermore, the transistors 205, 210 may be implemented in/over a silicon substrate (Si), a silicon carbide substrate (SiC), a gallium nitride substrate (GaN) or a gallium arsenide substrate (GaAs).

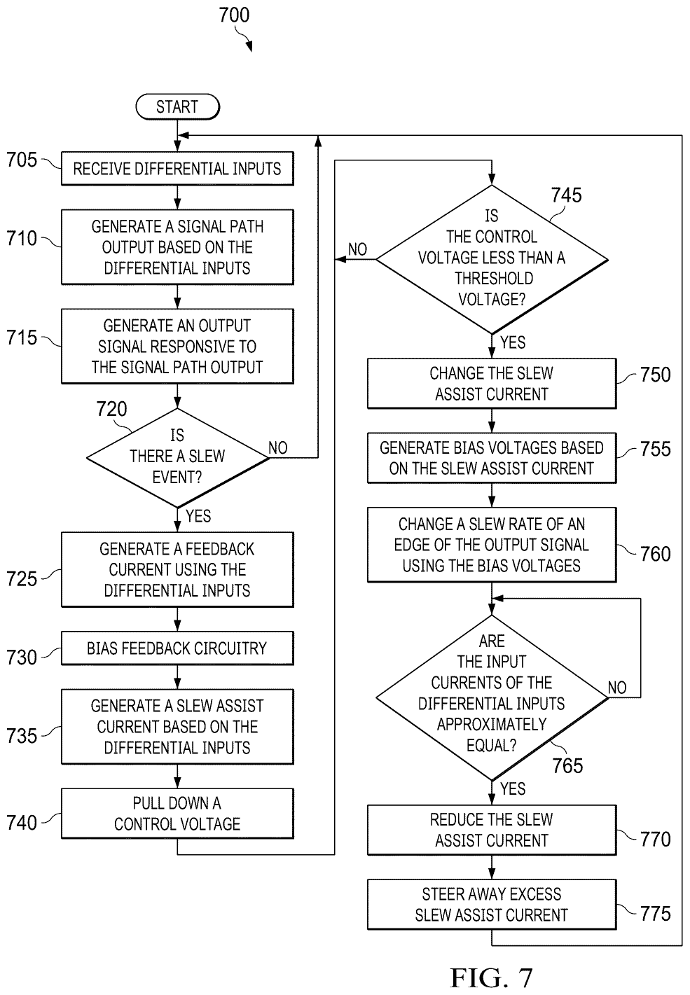

In example operation, the input stage circuitry 200 receives the first and second inputs from external circuitry. The input transistor circuitry 220 generates first and second intermediate signal path outputs responsive to the first and second inputs. In such example operations, the current mirror circuitry 245 generates the first and second bias voltages to mirror currents of the slew assist circuitry 240. During steady state operations (e.g., no transients at the first and second inputs), the slew assist circuitry 240 steers slew assist current from the current source circuitry 235 away from the current mirror circuitry 245. However, during slew event operations (e.g., a transient at the first and second inputs), the feedback circuitry 230 generates a feedback current that pulls down a control voltage and increases the slew assist current of the current source circuitry 235. Also, during slew event operations, the slew assist circuitry 240 begins to supply current to the current mirror circuitry 245, which generates the first and second bias voltages. Advantageously, the first and second bias voltages represent the increased slew assist current of the slew assist circuitry 240 during slew event operations. Advantageously, the slew assist circuitry 240 dynamically increases the slew rate of the output stage circuitry 110 during slew event operations of the input stage circuitry 200. Example operations of the input stage circuitry 200 are described further below in connection with FIG. 7.

FIG. 3 is a schematic diagram of example input stage circuitry 300, which is another example of the input stage circuitry 105, 200 of FIGS. 1 and 2. In the example of FIG. 3, the input stage circuitry 300 includes a first transistor 302, a second transistor 304, first current source circuitry 306, input transistor circuitry 308, bias circuitry 310, feedback circuitry 312, second current source circuitry 314, slew assist circuitry 316, and current mirror circuitry 318. The example input transistor circuitry 308 of FIG. 3 includes a third example transistor 320, a fourth example transistor 322, a fifth example transistor 324, and a sixth example transistor 326. The example bias circuitry 310 of FIG. 3 includes third example current source circuitry 328, a seventh example transistor 330, and a first example resistor 332. The example feedback circuitry 312 of FIG. 3 includes an eighth example transistor 334, a second example resistor 336, a ninth example transistor 338, a third example resistor 340, fourth example current source circuitry 342, an example capacitor 344, a tenth example transistor 346, a fourth example resistor 348, a fifth example resistor 350, an eleventh example transistor 352, a twelfth example transistor 354, a sixth example resistor 356, a thirteenth example transistor 358, and a fourteenth example transistor 360. The example current source circuitry 314 of FIG. 3 includes a seventh example resistor 362 and a fifteenth example transistor 364. The example slew assist circuitry 316 of FIG. 3 includes a sixteenth example transistor 366, a seventeenth example transistor 368, an eighteenth example transistor 370, a nineteenth example transistor 372, a twentieth example transistor 374, and a twenty-first example transistor 376. The example current mirror circuitry 318 of FIG. 3 includes a twenty-second example transistor 378 and a twenty-third example transistor 380.

The input stage circuitry 300 has a first input terminal, a second input terminal, a first output terminal, a second output terminal, a third output terminal, and a fourth output terminal. The first input terminal of the input stage circuitry 300 is structured to be coupled to external circuitry, which supplies a first input (IN1). The second input terminal of the input stage circuitry 300 is structured to be coupled to external circuitry which supplies a second input (IN2). The first and second output terminals of the input stage circuitry 300 are structured to be coupled to the driver circuitry 115 of FIG. 1. The input stage circuitry 300 supplies first and second intermediate signal path outputs (INT_{OUT1}, INT_{OUT2}) to the driver circuitry 115 at the first and second output terminals. The third output terminal of the input stage circuitry 300 is structured to be coupled to the transistor 135 of FIG. 1, which receives a first bias voltage (V_{BIAS1}) from the input stage circuitry 300. The fourth output terminal of the input stage circuitry 200 is structured to be coupled to the transistor 160 of FIG. 1, which receives a second bias voltage (V_{BIAS2}) from the input stage circuitry 300.

The transistor 302 is coupled to the transistor 304, the input transistor circuitry 308, the feedback circuitry 312, the slew assist circuitry 316, and the first input terminal of the input stage circuitry 300, which supplies the first input (IN1) from external circuitry. The transistor 302 is an example of the transistor 205 of FIG. 2. The transistor 304 is coupled to the transistor 302, the input transistor circuitry 308, the feedback circuitry 312, the slew assist circuitry 316, and the second input terminal of the input stage circuitry 300, which supplies the second input (IN2) from external circuitry. The transistor 304 is an example of the transistor 210 of FIG. 2.

The current source circuitry 306 is coupled to the input transistor circuitry 308 and a supply terminal, which supplies the supply voltage. The current source circuitry 306 is an example of the current source circuitry 215 of FIG. 2. The input transistor circuitry 308 is coupled to the transistors 302, 304, the feedback circuitry 312, the slew assist circuitry 316, and to the first and second output terminals of the input stage circuitry 300, which supply the first and second intermediate output signals (INT_{OUT1}, INT_{OUT2}) to the output stage circuitry 110 of FIG. 1. The input transistor circuitry 308 is an example of the input transistor circuitry 220 of FIG. 2.

The bias circuitry 310 is coupled to the feedback circuitry 312, the supply terminal, which supplies the supply voltage, and the common terminal, which supplies the common potential. The bias circuitry 310 is an example of the bias circuitry 225 of FIG. 2. The feedback circuitry 312 is coupled to the transistor 302, 304, the input transistor circuitry 308, the bias circuitry 310, the current source circuitry 314, and the slew assist circuitry 316. The feedback circuitry 312 is an example of the feedback circuitry 230 of FIG. 2.

The current source circuitry 314 is coupled to the feedback circuitry 312 and the slew assist circuitry 316. The current source circuitry 314 is an example of the current source circuitry 235 of FIG. 2. The slew assist circuitry 316 is coupled to the transistors 302, 304, the input transistor circuitry 308, the feedback circuitry 312, the current source circuitry 314, the current mirror circuitry 318, and the common terminal, which supplies the common potential. The slew assist circuitry 316 is an example of the slew assist circuitry 240 of FIG. 2. The current mirror circuitry 318 is coupled to the slew assist circuitry 316, the common terminal, which supplies the common potential, and the third and fourth output terminals of the input stage circuitry 300, which supply the first and second bias voltages (V_{BIAS1}, V_{BIAS2}) to the output stage circuitry 110. The current mirror circuitry 318 is an example of the current mirror circuitry 245 of FIG. 2.

The transistor 320 has a first terminal, a second terminal, a third terminal, and a control terminal. The first terminal of the transistor 320 is coupled to the current source circuitry 306 and the transistor 324. The second terminal of the transistor 320 is coupled to the transistor 322. The third terminal of the transistor 320 (also referred to as a bulk terminal) is coupled to the transistor 324 and may be coupled to common mode regulator circuitry, which regulates the common mode voltage (V_{CM}) of the input stage circuitry 300. The control terminal of the transistor 320 is coupled to the transistors 302, 322, the feedback circuitry 312, and the slew assist circuitry 316. The transistor 322 has a first terminal, a second terminal, and a control terminal. The first terminal of the transistor 322 is coupled to the transistor 320. The second terminal of the transistor 322 is coupled to the first output terminal of the input stage circuitry 300, which supplies the first intermediate output signal (INT_{OUT1}) to the driver circuitry 115 of FIG. 1, or more generally the output stage circuitry 110. The control terminal of the transistor 322 is coupled to the transistors 302, 320, the feedback circuitry 312, and the slew assist circuitry 316. The transistors 320, 322 are structured to generate a first intermediate signal path output based on the first input at the transistor 302.

The transistor 324 has a first terminal, a second terminal, a third terminal, and a control terminal. The first terminal of the transistor 324 is coupled to the current source circuitry 306 and the transistor 320. The second terminal of the transistor 324 is coupled to the transistor 326. The third terminal of the transistor 324 (also referred to as a bulk terminal) is coupled to the transistor 320 and may be coupled to common mode regulator circuitry, which regulates a common mode voltage (V_{CM}) of the input stage circuitry 300. The control terminal of the transistor 324 is coupled to the transistors 304, 326, the feedback circuitry 312, and the slew assist circuitry 316. The transistor 326 has a first terminal, a second terminal, and a control terminal. The first terminal of the transistor 326 is coupled to the transistor 324. The second terminal of the transistor 326 is coupled to the second output terminal of the input stage circuitry 300, which supplies the second intermediate output signal (INT_{OUT2}) to the driver circuitry 115, or more generally the output stage circuitry 110. The control terminal of the transistor 326 is coupled to the transistors 304, 324, the feedback circuitry 312, and the slew assist circuitry 316. The transistors 324, 326 are structured to generate a second intermediate signal path output based on the second input at the transistor 304.

The current source circuitry 328 has a first terminal and a second terminal. The first terminal of the current source circuitry 328 is coupled to the supply terminal, which supplies the supply voltage. The second terminal of the current source circuitry 328 is coupled to the feedback circuitry 312 and the transistor 330. The transistor 330 has a first terminal, a second terminal, and a control terminal. The first and control terminals of the transistor 330 are coupled to the feedback circuitry 312 and the current source circuitry 328. The second terminal of the transistor 330 is coupled to the resistor 332. The resistor 332 has a first terminal and a second terminal. The first terminal of the resistor 332 is coupled to the transistor 330. The second terminal of the resistor 332 is coupled to the common terminal, which supplies the common potential. In some examples, the resistor 332 is structured as a current limiting resistor, which limits a flow of current through the transistor 330. In the example of FIG. 3, the transistor 330 biases the feedback circuitry 312 by generating a control voltage at the control terminal of the transistor 330 proportional to the current from the current source circuitry 328.

The transistor 334 has a first terminal, a second terminal, and a control terminal. The first terminal of the transistor 334 is coupled to the current source circuitry 314, the transistors 338, 346, the current source circuitry 342, and the capacitor 344. The second terminal of the transistor 334 is coupled to the resistor 336 and the transistor 360. The control terminal of the transistor 334 is coupled to the bias circuitry 310 and the transistor 338. The resistor 336 has a first terminal and a second terminal. The first terminal of the resistor 336 is coupled to the transistors 334, 360. The second terminal of the resistor 336 is coupled to the common terminal, which supplies the common potential. In the example of FIG. 3, the resistor 336 is structured to control the transistor 334 responsive to current from the transistor 360.

The transistor 338 has a first terminal, a second terminal, and a control terminal. The first terminal of the transistor 338 is coupled to the current source circuitry 314, the transistors 334, 346, the current source circuitry 342, and the capacitor 344. The second terminal of the transistor 338 is coupled to the resistor 340 and the transistor 354. The control terminal of the transistor 338 is coupled to the bias circuitry 310 and the transistor 334. The resistor 340 has a first terminal and a second terminal. The first terminal of the resistor 340 is coupled to the transistors 338, 354. The second terminal of the resistor 340 is coupled to the common terminal, which supplies the common potential. In the example of FIG. 3, the resistor 340 is structured to control the transistor 338 responsive to current from the transistor 354.

The current source circuitry 342 has a first terminal and a second terminal. The first terminal of the current source circuitry 342 is coupled to the supply terminal, which supplies the supply voltage. The second terminal of the current source circuitry 342 is coupled to the current source circuitry 314, the transistors 334, 338, 346, and the capacitor 344. The capacitor 344 has a first terminal and a second terminal. The first terminal of the capacitor 344 is coupled to the supply terminal, which supplies the supply voltage. The second terminal of the capacitor 344 is coupled to current source circuitry 314, 342 and the transistors 334, 338, 346. In some examples, the current source circuitry 342 and the capacitor 344 are structured as pull-up circuitry, which pulls up a voltage to control the current source circuitry 314 and the transistor 346. In such examples, adjusting the current from the current source circuitry 342 or the capacitance of the capacitor 344 adjusts the duration that the current source circuitry 314 supplies the increased slew assist current.

The transistor 346 has a first terminal, a second terminal, and a control terminal. The first terminal of the transistor 346 is coupled to the resistor 348. The second terminal of the transistor 346 is coupled to the resistors 350, 356. The control terminal of the transistor 346 is coupled to the current source circuitry 314, 342, the transistors 334, 338, and the capacitor 344. The resistor 348 has a first terminal and a second terminal. The first terminal of the resistor 348 is coupled to the supply terminal, which supplies the supply voltage. The second terminal of the resistor 348 is coupled to the transistor 346. In some examples, the transistor 346 and the resistor 348 are structured as current source circuitry, which supplies a current to the resistors 350, 356 responsive to a voltage at the control terminal of the transistor 346. In such examples, the resistor 348 is structured as current limiting circuitry, which controls the current through the transistor 346.

The resistor 350 has a first terminal and a second terminal. The first terminal of the resistor 350 is coupled to the transistor 346 and the resistor 356. The second terminal of the resistor 350 is coupled to the transistor 352. The transistor 352 has a first terminal, a second terminal, a third terminal, and a control terminal. The first terminal of the transistor 352 is coupled to the resistor 350. The second terminal of the transistor 352 is coupled to the transistor 354. The third terminal of the transistor 352 (also referred to as a bulk terminal) is coupled to the transistors 302, 304, 358 and the slew assist circuitry 316. The control terminal of the transistor 352 is coupled to the transistors 302, 354, the input transistor circuitry 308, and the slew assist circuitry 316. The transistor 354 has a first terminal, a second terminal, and a control terminal. The first terminal of the transistor 354 is coupled to the transistor 352. The second terminal of the transistor 354 is coupled to the transistor 338 and the resistor 340. The control terminal of the transistor 354 is coupled to the transistors 302, 352, the input transistor circuitry 308, and the slew assist circuitry 316. In the example of FIG. 3, the resistor 350 and the transistors 352, 354 are structured to form a first current path for a feedback current based on the transistor 302.

The resistor 356 has a first terminal and a second terminal. The first terminal of the resistor 356 is coupled to the transistor 346 and the resistor 350. The second terminal of the resistor 356 is coupled to the transistor 358. The transistor 358 has a first terminal, a second terminal, a third terminal, and a control terminal. The first terminal of the transistor 358 is coupled to the resistor 356. The second terminal of the transistor 358 is coupled to the transistor 360. The third terminal of the transistor 358 (also referred to as a bulk terminal) is coupled to the transistors 302, 304 and the slew assist circuitry 316. The control terminal of the transistor 358 is coupled to the transistors 304, 360, the input transistor circuitry 308, and the slew assist circuitry 316. The transistor 360 has a first terminal, a second terminal, and a control terminal. The first terminal of the transistor 360 is coupled to the transistor 358. The second terminal of the transistor 360 is coupled to the transistor 334 and the resistor 336. The control terminal of the transistor 360 is coupled to the transistors 304, 358, the input transistor circuitry 308, and the slew assist circuitry 316. In the example of FIG. 3, the resistor 356 and the transistors 358, 360 are structured to form a second current path for the feedback current based on the transistor 304.

The resistor 362 has a first terminal and a second terminal. The first terminal of the resistor 362 is coupled to the supply terminal, which supplies the supply voltage. The second terminal of the resistor 362 is coupled to the transistor 364. The transistor 364 has a first terminal, a second terminal, and a control terminal. The first terminal of the transistor 364 is coupled to the resistor 362. The second terminal of the transistor 364 is coupled to the slew assist circuitry 316. The control terminal of the transistor 364 is coupled to the feedback circuitry 312.

The transistor 366 has a first terminal, a second terminal, a third terminal, and a control terminal. The first terminal of the transistor 366 is coupled to the current source circuitry 314 and the transistor 370. The second terminal of the transistor 366 is coupled to the transistors 368, 376. The third terminal of the transistor 366 (also referred to as a bulk terminal) is coupled to the transistors 302, 304, 370 and the feedback circuitry 312. The control terminal of the transistor 366 is coupled to the transistors 302, 368, 374, the input transistor circuitry 308, and the feedback circuitry 312. The transistor 368 has a first terminal, a second terminal, and a control terminal. The first terminal of the transistor 368 is coupled to the transistors 366, 376. The second terminal of the transistor 368 is coupled to the current mirror circuitry 318. The control terminal of the transistor 368 is coupled to the transistors 302, 366, 374, the input transistor circuitry 308, and the feedback circuitry 312. In the example of FIG. 3, the transistors 366, 368 are structured to form a first current path for the slew assist current based on the transistor 302.

The transistor 370 has a first terminal, a second terminal, a third terminal, and a control terminal. The first terminal of the transistor 370 is coupled to the current source circuitry 314 and the transistor 366. The second terminal of the transistor 370 is coupled to the transistors 372, 374. The third terminal of the transistor 370 (also referred to as a bulk terminal) is coupled to the transistors 302, 366, the input transistor circuitry 308, and the feedback circuitry 312. The control terminal of the transistor 370 is coupled to the transistors 304, 372, 376, the input transistor circuitry 308, and the feedback circuitry 312. The transistor 372 has a first terminal, a second terminal, and a control terminal. The first terminal of the transistor 372 is coupled to the transistors 370, 374. The second terminal of the transistor 372 is coupled to the current mirror circuitry 318. The control terminal of the transistor 372 is coupled to the transistors 304, 370, 376, the input transistor circuitry 308, and the feedback circuitry 312. In the example of FIG. 3, the transistors 370, 372 are structured to form a second current path for the slew assist current based on the transistor 304.

The transistor 374 has a first terminal, a second terminal, and a control terminal. The first terminal of the transistor 374 is coupled to the transistors 370, 372. The second terminal of the transistor 374 is coupled to the common terminal, which supplies the common potential. The control terminal of the transistor 374 is coupled to the transistors 302, 366, 368, the input transistor circuitry 308, and the feedback circuitry 312. In the example of FIG. 3, the transistor 374 is structured to adjust the second current path of the slew assist current to steer away current based on the transistor 302.

The transistor 376 has a first terminal, a second terminal, and a control terminal. The first terminal of the transistor 376 is coupled to the transistors 366, 368. The second terminal of the transistor 376 is coupled to the common terminal, which supplies the common potential. The control terminal of the transistor 376 is coupled to the transistors 304, 370, 372, the input transistor circuitry 308, and the feedback circuitry 312. In the example of FIG. 3, the transistor 376 is structured to adjust the first current path of the slew assist current to steer away current based on the transistor 304.

The transistor 378 has a first terminal, a second terminal, and a control terminal. The first and control terminals of the transistor 378 are coupled to the slew assist circuitry 316 and the third output terminal of the input stage circuitry 300, which supplies the first bias voltage (V_{BIAS1}) to the power stage circuitry 120 of FIG. 1, or even more generally the output stage circuitry 110. The second terminal of the transistor 378 is coupled to the common terminal, which supplies the common potential. In the example of FIG. 3, the transistor 378 generates the first bias voltage responsive to current from the slew assist circuitry 316. In such examples, the transistor 378 is structured to control the transistor 160, which sinks a current proportional to the current through the transistor 378 responsive to the first bias voltage.

The transistor 380 has a first terminal, a second terminal, and a control terminal. The first and control terminals of the transistor 380 are coupled to the slew assist circuitry 316 and the fourth output terminal of the input stage circuitry 300, which supplies the second bias voltage (V_{BIAS2}) to the power stage circuitry 120, or even more generally the output stage circuitry 110. The second terminal of the transistor 378 is coupled to the common terminal, which supplies the common potential. In the example of FIG. 3, the transistor 380 generates the second bias voltage responsive to current from the slew assist circuitry 316. In such examples, the transistor 380 is structured to control the transistor 135, which sinks a current proportional to the current through the transistor 380 responsive to the second bias voltage.

In the example of FIG. 3, the transistors 302, 304 are n-channel MOSFETs. Alternatively, the transistors 302, 304 may be n-channel FETs, n-channel IGBTs, n-channel JFETs, NPN BJTs or, with slight modifications, p-type equivalent devices. In the example of FIG. 3, the transistors 320, 322, 324, 326, 346, 352, 354, 358, 360, 364, 366, 368, 370, 372, 374, 376 are p-channel MOSFETs. Alternatively, the transistors 320, 322, 324, 326, 346, 352, 354, 358, 360, 364, 366, 368, 370, 372, 374, 376 may be p-channel FETs, p-channel IGBTs, p-channel JFETs, PNP BJTs, or, with slight modifications, n-type equivalent devices. In the example of FIG. 3, the transistors 330, 334, 338, 378, 380 are NPN BJTs. Alternatively, the transistors 330, 334, 338, 378, 380 may be n-channel MOSFETs, n-channel FETs, n-channel IGBTs, n-channel JFETs or, with slight modifications, p-type equivalent devices. The transistors 302, 304, 320, 322, 324, 326, 330, 334, 338, 346, 352, 354, 358, 360, 364, 366, 368, 370, 372, 374, 376, 378, 380 may be depletion mode devices, drain-extended devices, enhancement mode devices, natural transistors or other type of device structure transistors. Furthermore, the transistors 302, 304, 320, 322, 324, 326, 330, 334, 338, 346, 352, 354, 358, 360, 364, 366, 368, 370, 372, 374, 376, 378, 380 may be implemented in/over a silicon substrate (Si), a silicon carbide substrate (SiC), a gallium nitride substrate (GaN) or a gallium arsenide substrate (GaAs).

In example operations, the transistors 302, 304 receive one of the first input or the second input. The transistors 320, 322 generate the first intermediate signal path output responsive to the first input at the transistor 302 and the transistor 324, 326 generate the second intermediate signal path output responsive to the second input at the transistor 304. During steady state operations (e.g., no transient at the transistors 302, 304), the current source circuitry 342 and the capacitor 344 pull-up the control terminals of the transistors 346, 364, which reduces the feedback current and slew assist currents. In such example operations, the transistors 368, 370, 374, 376 implement minimum selector control, which uses the transistors 374, 376 to sink the slew assist current and reduce any current to the transistors 378, 380. Advantageously, during steady state operations, the feedback circuitry 312 structures the current source circuitry 314 to supply a reduced slew assist current. Also, the slew assist circuitry 316 further reduces the supply of a slew assist current to the current mirror circuitry 318 by implementing a minimum selector bias of the transistors 374, 376. In such examples, the transistors 374, 376 have a cascode bias resulting from sizing the transistors 374, 376 in relation to the transistors 368, 372. Advantageously, the cascode bias of the transistors 368, 372, 374, 376 reduces currents through the transistors 368, 372 when the transistors 374, 376 are conducting current. Such a cascode bias is further described in connection with FIG. 7, below.

In other example operations, during slew event operations (e.g., transient at the transistors 302, 304), the transient inputs structure one of the first or second feedback current paths through the transistors 352, 354, 358, 360. The one of the first or second feedback currents turn off one of the transistors 334, 338 and strongly turns on the other one of the transistors 334, 338. The other one of the transistors 334, 338 pulls down the control terminals of the transistors 346, 364 to increase the feedback current and slew assist current. Also, the transient inputs structure one of the first or second slew assist current paths through the transistors 366, 368, 370, 372. The one of the first or second slew assist current paths that supply the increased slew assist current to one of the transistors 378, 380 is referred to as the preferred path. The one of the transistors 378, 380 coupled to the preferred path generate a bias voltage which increases the slew rate of the amplifier circuitry 100. Advantageously, the slew assist circuitry 316 dynamically supplies the increased slew assist current to the current mirror circuitry 318 during slew event operations. Example operations of the input stage circuitry 300 are described further below in connection with FIG. 7.

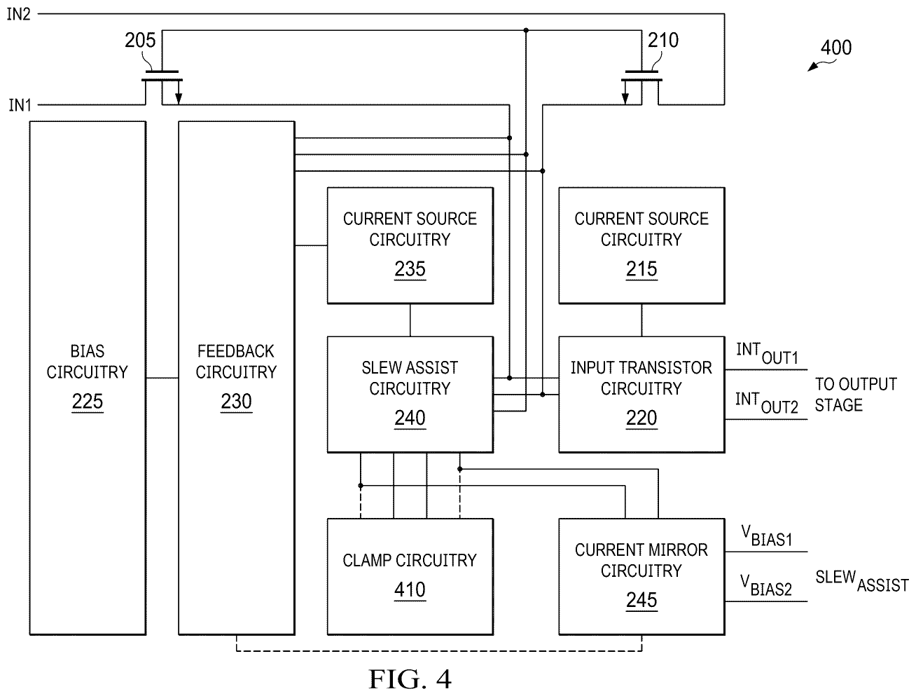

FIG. 4 is a block diagram of example input stage circuitry 400, which is yet another example of the input stage circuitry 105, 200, 300 of FIGS. 1, 2, and 3. In the example of FIG. 4, the input stage circuitry 400 includes the transistors 205, 210 of FIG. 2, the current source circuitry 215, 235 of FIG. 2, the input transistor circuitry 220 of FIG. 2, the bias circuitry 225 of FIG. 2, the feedback circuitry 230 of FIG. 2, the slew assist circuitry 240 of FIG. 2, the current mirror circuitry 245 of FIG. 2, and clamp circuitry 410.

The input stage circuitry 400 has a first input terminal, a second input terminal, a first output terminal, a second output terminal, a third output terminal, and a fourth output terminal. The first input terminal of the input stage circuitry 400 is structured to be coupled to external circuitry, which supplies a first input (IN1). The second input terminal of the input stage circuitry 400 is structured to be coupled to external circuitry which supplies a second input (IN2). The first and second output terminals of the input stage circuitry 400 are structured to be coupled to the driver circuitry 115 of FIG. 1. The input stage circuitry 400 supplies first and second intermediate signal path outputs (INT_{OUT1}, INT_{OUT2}) to the driver circuitry 115 at the first and second output terminals. The third output terminal of the input stage circuitry 400 is structured to be coupled to the transistor 135 of FIG. 1, which receives a first bias voltage (V_{BIAS1}) from the input stage circuitry 400. The fourth output terminal of the input stage circuitry 400 is structured to be coupled to the transistor 160 of FIG. 1, which receives a second bias voltage (V_{BIAS2}) from the input stage circuitry 400.

In the example of FIG. 4, the feedback circuitry 230 has a first terminal, a second terminal, a third terminal, a fourth terminal, a fifth terminal, and may be structured to have a sixth terminal. The first terminal of the feedback circuitry 230 is coupled to the transistor 205, the input transistor circuitry 220, and the slew assist circuitry 240. The second terminal of the feedback circuitry 230 is coupled to the transistor 210, the input transistor circuitry 220, and the slew assist circuitry 240. The third terminal of the feedback circuitry 230 is coupled to the transistors 205, 210, the slew assist circuitry 240, and may be coupled to common mode regulator circuitry, which regulates the common mode voltage of the input stage circuitry 200. The fourth terminal of the feedback circuitry 230 is coupled to the bias circuitry 225. The fifth terminal of the feedback circuitry 230 is coupled to the current source circuitry 235. The sixth terminal of the feedback circuitry 230 is coupled to the current mirror circuitry 245. An example of the feedback circuitry 230 is illustrated and described in connection with FIGS. 3, 5, and 6.

In the example of FIG. 4, the slew assist circuitry 240 has a first terminal, a second terminal, a third terminal, a fourth terminal, a fifth terminal, a sixth terminal, a seventh terminal, and an eighth terminal. The first terminal of the slew assist circuitry 240 is coupled to the transistor 205, the input transistor circuitry 220, and the feedback circuitry 230. The second terminal of the slew assist circuitry 240 is coupled to the transistor 210, the input transistor circuitry 220, and the feedback circuitry 230. The third terminal of the slew assist circuitry 240 is coupled to the transistors 205, 210 and may be coupled to common mode regulator circuitry, which regulates the common mode voltage of the input stage circuitry 200. The fourth and fifth terminals of the slew assist circuitry 240 are coupled to the current mirror circuitry 245 and may be coupled to the clamp circuitry 410. The seventh and eighth terminals of the slew assist circuitry 240 are coupled to the clamp circuitry 410. An example of the slew assist circuitry 240 is illustrated and described in connection with FIGS. 3, 5, and 6.

In the example of FIG. 4, the current mirror circuitry 245 has a first terminal, a second terminal, a third terminal, a fourth terminal, and may have a fifth terminal. The first and second terminals of the current mirror circuitry 245 are coupled to the slew assist circuitry 240 and may be coupled to the clamp circuitry 410. The third and fourth terminals of the current mirror circuitry 245 are structured to be coupled to the power stage circuitry 120 of FIG. 1, or more generally the output stage circuitry 110. The fifth terminal of the current mirror circuitry 245 is coupled to the feedback circuitry 230. Examples of the current mirror circuitry 245 are illustrated and described in FIGS. 3, 5, and 6.

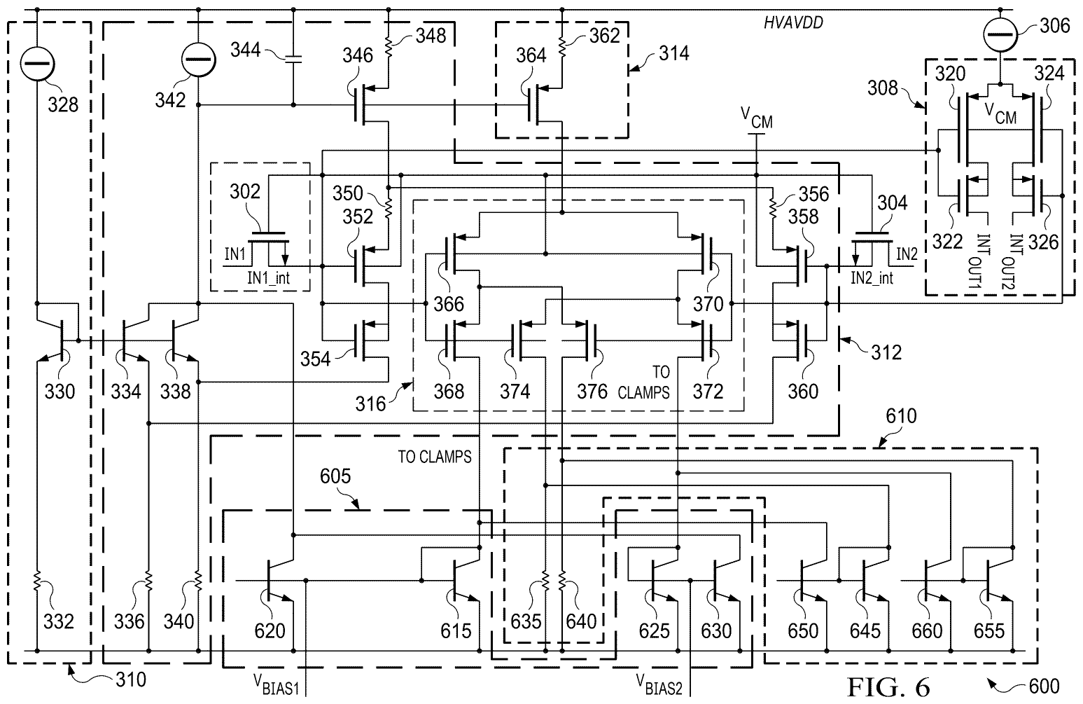

The clamp circuitry 410 has a first terminal, a second terminal, and may have a third terminal and a fourth terminal. The first and second terminals of the clamp circuitry 410 are coupled to the slew assist circuitry 240. The third and fourth terminals of the clamp circuitry 410 are coupled to the slew assist circuitry 240 and the current mirror circuitry 245. Examples of the clamp circuitry 410 are illustrated and described in connection with FIGS. 5 and 6, below.

In the example of FIG. 4, the transistors 205, 210 are n-channel MOSFETs. Alternatively, the transistors 205, 210 may be n-channel FETs, n-channel IGBTs, n-channel JFETs, NPN BJTs or, with slight modifications, p-type equivalent devices. The transistors 205, 210 may be depletion mode devices, drain-extended devices, enhancement mode devices, natural transistors or other types of device structure transistors. Furthermore, the transistors 205, 210 may be implemented in/over a silicon substrate (Si), a silicon carbide substrate (SiC), a gallium nitride substrate (GaN) or a gallium arsenide substrate (GaAs).

In example operations, the clamp circuitry 410 generates first and second clamp voltages responsive to currents from the slew assist circuitry 240. The first and second clamp voltages are structured to reduce a supply of the slew assist currents from the slew assist circuitry 240 to the current mirror circuitry 245. Advantageously, the clamp circuitry 410 reduces a supply of slew assist current to the current mirror circuitry 245 using the first and second clamp voltages. Advantageously, the clamp circuitry 410 is configured to clamp the slew assist circuitry 240 using the first and second clamp voltages. Example operations of the input stage circuitry 400 are described further below in connection with FIG. 7.

FIG. 5 is a schematic diagram of example input stage circuitry 500, which is another example of the input stage circuitry 105, 200, 300, 400 of FIGS. 1, 2, 3, and 4. In the example of FIG. 5, the input stage circuitry 500 includes the transistors 302, 304 of FIG. 3, the current source circuitry 306, 314 of FIG. 3, the input transistor circuitry 308 of FIG. 3, the bias circuitry 310 of FIG. 3, the feedback circuitry 312 of FIG. 3, the slew assist circuitry 316 of FIG. 3, the current mirror circuitry 318 of FIG. 3, and clamp circuitry 510. The example input transistor circuitry 308 of FIG. 5 includes the transistors 320, 322, 324, 326 of FIG. 3. The example bias circuitry 310 of FIG. 5 includes the current source circuitry 328 of FIG. 3, the transistor 330 of FIG. 3, and the resistor 332 of FIG. 3. The example feedback circuitry 312 of FIG. 5 includes the transistors 334, 338, 346, 352, 354, 358, 360 of FIG. 3, the resistors 336, 340, 348, 356 of FIG. 3, the current source circuitry 342 of FIG. 3, and the capacitor 344 of FIG. 3. The example current source circuitry 314 of FIG. 5 includes the resistor 362 of FIG. 3 and the transistor 364 of FIG. 3. The example slew assist circuitry 316 of FIG. 5 includes the transistors 366, 368, 370, 372, 374, 376 of FIG. 3. The example current mirror circuitry 318 of FIG. 5 includes the transistors 378, 380 of FIG. 3. The example clamp circuitry 510 of FIG. 5 includes a first example resistor 520 and a second example resistor 530.

The input stage circuitry 500 has a first input terminal, a second input terminal, a first output terminal, a second output terminal, a third output terminal, and a fourth output terminal. The first input terminal of the input stage circuitry 500 is structured to be coupled to external circuitry, which supplies a first input (IN1). The second input terminal of the input stage circuitry 500 is structured to be coupled to external circuitry which supplies a second input (IN2). The first and second output terminals of the input stage circuitry 500 are structured to be coupled to the driver circuitry 115 of FIG. 1. The input stage circuitry 500 supplies first and second intermediate signal path outputs (INT_{OUT1}, INT_{OUT2}) to the driver circuitry 115 at the first and second output terminals. The third output terminal of the input stage circuitry 500 is structured to be coupled to the transistor 135 of FIG. 1, which receives a first bias voltage (V_{BIAS1}) from the input stage circuitry 500. The fourth output terminal of the input stage circuitry 500 is structured to be coupled to the transistor 160 of FIG. 1, which receives a second bias voltage (V_{BIAS2}) from the input stage circuitry 500.

In the example of FIG. 5, the slew assist circuitry 316 is coupled to the transistors 302, 304, the input transistor circuitry 308, the feedback circuitry 312, the current source circuitry 314, the current mirror circuitry 318, and the clamp circuitry 510. The slew assist circuitry 316 is an example of the slew assist circuitry 240 of FIGS. 2 and 4. The clamp circuitry 510 is coupled to the slew assist circuitry 316 and the common terminal, which supplies the common potential. The clamp circuitry 510 is an example of the clamp circuitry 410 of FIG. 4.

The resistor 520 has a first terminal and a second terminal. The first terminal of the resistor 520 is coupled to the transistor 374, or more generally the slew assist circuitry 316. The second terminal of the resistor 520 is coupled to the common terminal, which supplies the common potential. The resistor 530 has a first terminal and a second terminal. The first terminal of the resistor 530 is coupled to the transistor 376, or more generally the slew assist circuitry 316. The second terminal of the resistor 530 is coupled to the common terminal, which supplies the common potential.

In example operation, the resistor 520 generates a first clamp voltage responsive to current from the transistor 374 and the resistor 530 generates a second clamp voltage responsive to current from the transistor 376. In such example operations, the first clamp voltage biases the transistor 374 to turn off the transistor 368 and the second clamp voltage biases the transistor 376 to turn off the transistor 372. Advantageously, the first and second clamp voltages further reduce slew assist current being supplied to the current mirror circuitry 318 by fully disabling the transistors 368, 372. Example operations of the input stage circuitry 500 are described further below in connection with FIG. 7.

FIG. 6 is a schematic diagram of example input stage circuitry 600, which is another example of the input stage circuitry 105, 200, 300, 400, 500 of FIGS. 1, 2, 3, 4, and 5. In the example of FIG. 6, the input stage circuitry 600 includes the transistors 302, 304 of FIGS. 3 and 5, the current source circuitry 306, 314 of FIGS. 3 and 5, the input transistor circuitry 308 of FIGS. 3 and 5, the bias circuitry 310 of FIGS. 3 and 5, the feedback circuitry 312 of FIGS. 3 and 5, the slew assist circuitry 316 of FIGS. 3 and 5, current mirror circuitry 605, and clamp circuitry 610. The example input transistor circuitry 308 of FIG. 6 includes the transistors 320, 322, 324, 326 of FIGS. 3 and 5. The example bias circuitry 310 of FIG. 6 includes the current source circuitry 328 of FIGS. 3 and 5, the transistor 330 of FIGS. 3 and 5, and the resistor 332 of FIGS. 3 and 5. The example feedback circuitry 312 of FIG. 6 includes the transistors 334, 338, 346, 352, 354, 358, 360 of FIGS. 3 and 5, the resistors 336, 340, 348, 356 of FIGS. 3 and 5, the current source circuitry 342 of FIGS. 3 and 5, and the capacitor 344 of FIGS. 3 and 5. The example current source circuitry 314 of FIG. 6 includes the resistor 362 of FIGS. 3 and 5 and the transistor 364 of FIGS. 3 and 5. The example slew assist circuitry 316 of FIG. 6 includes the transistors 366, 368, 370, 372, 374, 376 of FIGS. 3 and 5. The example current mirror circuitry 605 of FIG. 6 includes a first example transistor 615, a second example transistor 620, a third example transistor 625, and a fourth example transistor 630. The example clamp circuitry 610 of FIG. 6 includes a first example resistor 635, a second example resistor 640, a fifth example transistor 645, a sixth example transistor 650, a seventh example transistor 655, and an eighth example transistor 660.

The input stage circuitry 600 has a first input terminal, a second input terminal, a first output terminal, a second output terminal, a third output terminal, and a fourth output terminal. The first input terminal of the input stage circuitry 600 is structured to be coupled to external circuitry, which supplies a first input (IN1). The second input terminal of the input stage circuitry 600 is structured to be coupled to external circuitry which supplies a second input (IN2). The first and second output terminals of the input stage circuitry 600 are structured to be coupled to the driver circuitry 115 of FIG. 1. The input stage circuitry 600 supplies first and second intermediate signal path outputs (INT_{OUT1}, INT_{OUT2}) to the driver circuitry 115 at the first and second output terminals. The third output terminal of the input stage circuitry 600 is structured to be coupled to the transistor 135 of FIG. 1, which receives a first bias voltage (V_{BIAS1}) from the input stage circuitry 600. The fourth output terminal of the input stage circuitry 600 is structured to be coupled to the transistor 160 of FIG. 1, which receives a second bias voltage (V_{BIAS2}) from the input stage circuitry 600.

The current mirror circuitry 605 is coupled to the feedback circuitry 312, the slew assist circuitry 316, the clamp circuitry 610, and the third and fourth output terminals of the input stage circuitry 600, which supply the first and second bias voltages (V_{BIAS1}, V_{BIAS2}) to the power stage circuitry 120 of FIG. 1, or more generally the output stage circuitry 110 of FIG. 1. The current mirror circuitry 605 is another example of the current mirror circuitry 245, 318 of FIGS. 2, 3, 4, and 5. The clamp circuitry 610 is coupled to the slew assist circuitry 316 and the current mirror circuitry 605. The clamp circuitry 610 is another example of the clamp circuitry 410, 510 of FIGS. 4 and 5.

The transistor 615 has a first terminal, a second terminal, and a control terminal. The first and control terminals of the transistor 615 are coupled to the transistor 368, or more generally the slew assist circuitry 316, the clamp circuitry 610, the transistor 620, and the third output terminal of the input stage circuitry 600, which supplies the first bias voltage (V_{BIAS1}) to the output stage circuitry 110. The second terminal of the transistor 615 is coupled to the common terminal, which supplies the common potential. The transistor 620 has a first terminal, a second terminal, and a control terminal. The first terminal of the transistor 620 is coupled to the transistors 334, 338, 346, or more generally the feedback circuitry 312, and the transistor 630. The second terminal of the transistor 620 is coupled to the common terminal, which supplies the common potential. The control terminal of the transistor 620 is coupled to the slew assist circuitry 316, the clamp circuitry 610, the transistor 615, and the third output terminal of the input stage circuitry 600, which supplies the first bias voltage (V_{BIAS1}) to the output stage circuitry 110.

The transistor 625 has a first terminal, a second terminal, and a control terminal. The first and control terminals of the transistor 625 are coupled to the transistor 372, or more generally the slew assist circuitry 316, the clamp circuitry 610, the transistor 630, and the fourth output terminal of the input stage circuitry 600, which supplies the second bias voltage (V_{BIAS2}) to the output stage circuitry 110. The second terminal of the transistor 625 is coupled to the common terminal, which supplies the common potential. The transistor 630 has a first terminal, a second terminal, and a control terminal. The first terminal of the transistor 630 is coupled to the feedback circuitry 312 and the transistor 620. The second terminal of the transistor 630 is coupled to the common terminal, which supplies the common potential. The control terminal of the transistor 630 is coupled to the slew assist circuitry 316, the clamp circuitry 610, the transistor 625, and the fourth output terminal of the input stage circuitry 600, which supplies the second bias voltage (V_{BIAS2}) to the output stage circuitry 110.

The resistor 635 has a first terminal and a second terminal. The first terminal of the resistor 635 is coupled to the slew assist circuitry 316 and the transistors 645, 650. The second terminal of the resistor 635 is coupled to the common terminal, which supplies the common potential. The resistor 635 is another example of the resistor 520 of FIG. 5. The resistor 640 has a first terminal and a second terminal. The first terminal of the resistor 640 is coupled to the slew assist circuitry 316 and the transistors 655, 660. The second terminal of the resistor 640 is coupled to the common terminal, which supplies the common potential. The resistor 640 is another example of the resistor 530 of FIG. 5.

The transistor 645 has a first terminal, a second terminal, and a control terminal. The first and control terminals of the transistor 645 are coupled to the slew assist circuitry 316, the resistor 635, and the transistor 650. The second terminal of the transistor 645 is coupled to the common terminal, which supplies the common potential. The transistor 650 has a first terminal, a second terminal, and a control terminal. The first terminal of the transistor 650 is coupled to the slew assist circuitry 316 and the current mirror circuitry 605. The second terminal of the transistor 650 is coupled to the common terminal, which supplies the common potential. The control terminal of the transistor 650 is coupled to the slew assist circuitry 316, the resistor 635, and the transistor 645.

The transistor 655 has a first terminal, a second terminal, and a control terminal. The first and control terminals of the transistor 655 are coupled to the slew assist circuitry 316, the resistor 640, and the transistor 660. The second terminal of the transistor 655 is coupled to the common terminal, which supplies the common potential. The transistor 660 has a first terminal, a second terminal, and a control terminal. The first terminal of the transistor 660 is coupled to the slew assist circuitry 316 and the current mirror circuitry 605. The second terminal of the transistor 660 is coupled to the common terminal, which supplies the common potential. The control terminal of the transistor 660 is coupled to the slew assist circuitry 316, the resistor 640, and the transistor 655.

In the example of FIG. 6, the transistors 615, 620, 625, 630, 645, 650, 655, 660 are NPN BJTs. Alternatively, the transistors 615, 620, 625, 630, 645, 650, 655, 660 may be n-channel MOSFETs, n-channel FETs, n-channel IGBTs, n-channel JFETs or, with slight modifications, p-type equivalent devices. The transistors 615, 620, 625, 630, 645, 650, 655, 660 may be depletion mode devices, drain-extended devices, enhancement mode devices, natural transistors or other type of device structure transistors. Furthermore, the transistors 615, 620, 625, 630, 645, 650, 655, 660 may be implemented in/over a silicon substrate (Si), a silicon carbide substrate (SiC), a gallium nitride substrate (GaN) or a gallium arsenide substrate (GaAs).

In example operation, the transistors 620, 630 mirror currents through the transistors 615, 625, which represent the slew assist current. The transistors 620, 630 increase the speed at which the feedback circuitry 312 pulls down the control terminals of the transistors 346, 364. The transistors 645, 655 mirror current through the resistors 635, 640. The transistors 650, 660 sink the current through the resistors 635, 640 from the slew assist circuitry 316. Advantageously, the transistors 650, 660 reduce the slew assist currents supplied to the current mirror circuitry 605 when current is flowing through the resistors 635, 640. Advantageously, the transistors 650, 660 reduce a likelihood of the transistors 620, 630 pulling down the control terminal of the transistors 346, 364 using non-ideal slew assist currents from the slew assist circuitry 316. Example operations of the input stage circuitry 600 are described further below in connection with FIG. 7.

FIG. 7 is a flowchart representative of example operations 700 that may be at least one of executed, instantiated, or performed using an example implementation of the input stage circuitry 105, 200, 300, 400, 500, 600 of FIGS. 1, 2, 3, 4, 5, and 6, or more generally the amplifier circuitry 100 of FIG. 1. The example operations 700 of FIG. 7 begin at Block 705 at which the transistors 205, 210, 302, 304 of FIGS. 2, 3, 4, 5, and 6 receive differential inputs. (Block 705). In some examples, external circuitry supplies first and second input signals to the transistors 205, 210, 302, 304. For example, programmable circuitry may supply a pulse width modulation (PWM) signal to the first and second inputs of the amplifier circuitry 100. In such examples, the PWM signal controls the transistors 205, 210, 302, 304.

The input transistor circuitry 220, 308 of FIGS. 2, 3, 4, 5, and 6 generates a signal path output based on the differential inputs. (Block 710). In some examples, the transistors 205, 210, 302, 304 control the input transistor circuitry 220, 308 responsive to the differential input signal at the inputs of the amplifier circuitry 100. In such examples, transistors 320, 322 generate a first signal path output and the transistors 324, 326 generate a second signal path output. For example, when a first input signal turns on the transistors 205, 302 and a second input signal turns off the transistors 210, 304, the transistors 320, 322 are turned off and the transistors 324, 326 are turned on. In such an example, the transistors 320, 322 generate a first signal path output having a logical low state and the transistors 324, 326 generate a second signal path output having a logical high state. In the example of FIG. 7, the signals from the input transistor circuitry 220, 308 are a part of the input signal path responsive to the first and second signal path outputs representing the received input signals.

The output stage circuitry 110 of FIG. 1 generates an output signal responsive to the signal path output. (Block 715). In some described examples, the driver circuitry 115 of FIG. 1 receives the signal path outputs from the input stage circuitry 105. In such examples, the driver circuitry 115 generates high-side and low-side control signals responsive to the signal path outputs. For example, the driver circuitry 115 may be class AB amplifier, which implements AB control to generate the high-side and low-side control signals. In AB control, the high-side and low-side control signals can control the transistors 125, 150 in a linear region of operation (e.g., partially conducting current). Such control allows the power stage circuitry 120 to generate the output signal as an analog value.

The feedback circuitry 230, 312 of FIGS. 2, 3, 4, 5, and 6 and the slew assist circuitry 240, 316 of FIGS. 2, 3, 4, 5, and 6 determine if there is a slew event. (Block 720). In some examples, the feedback circuitry 230, 312 and the slew assist circuitry 240, 316 switch between two modes of operation. In a first mode of operation (also referred to as steady state operation), the feedback circuitry 230, 312 and the slew assist circuitry 240, 316 have settled responsive to currents of the transistors 205, 210, 302, 304 being fixed values. In such steady state operation, the transistors 352, 354, 358, 360 of FIG. 3 supply a fixed current to the resistors 336, 340 of FIG. 3 and the transistors 376, 374 of FIG. 3 sink current from the current source circuitry 235, 314 of FIGS. 2, 3, 4, 5, and 6. In a second mode of operation (also referred to as a slew event operation), the feedback circuitry 230, 312 and the slew assist circuitry 240, 316 transition from a first current path to a second current path responsive to the transistor 205, 210, 302, 304 receiving transient input signals. For example, a rising edge of a first input signal switches the transistors 205, 302 from being turned off to being turned on and a falling edge of the second input signal transitions the transistors 210, 304 from being turned on to being turned off. Such slew event operations are further described in connection with Blocks 725-775, below.

If the feedback circuitry 230, 312 and the slew assist circuitry 240, 316 determine there is no slew event (e.g., Block 720 returns a result of NO), control proceeds to return to block 705. For example, the feedback circuitry 230, 312 and the slew assist circuitry 240, 316 remain in the steady state operation.

If the feedback circuitry 230, 312 and the slew assist circuitry 240, 316 determine there is a slew event (e.g., Block 720 returns a result of YES), the feedback circuitry 230, 312 generates a feedback current using the differential inputs. (Block 725). In some examples, the feedback circuitry 230, 312 generates a feedback current through a first current path or a second current path. The first current path of the feedback circuitry 230, 312 is controlled by the transistors 205, 302 and flows through the resistors 340, 350 and the transistors 346, 352, 354. The second current path of the feedback circuitry 230, 312 is controlled by the transistors 210, 304 and flows through the resistors 336, 356 and the transistors 346, 358, 360. When a slew event occurs (e.g., a rising edge at one input and a falling edge at another input), the feedback circuitry 230, 312 generates a feedback current by turning on transistors of one of the first or second current paths and turning off transistors of the other one of the first or second current paths. For example, when the first input signal turns off the transistors 205, 302 and the second input signal turns on the transistors 210, 304, the transistors 352, 354 turn on and the transistors 358, 360 turn off. In such an example, the transistors 352, 354 supply a feedback current to the resistor 340.

The bias circuitry 225, 310 of FIGS. 2, 3, 4, 5, and 6 biases feedback circuitry. (Block 730). In some examples, the bias circuitry 225, 310 is structured as current mirror circuitry, which generates a reference voltage that biases the feedback circuitry 312. For example, the transistor 330 of FIGS. 3, 5, and 6 controls the transistors 334, 338 to source a current approximately equal to the current from the current source circuitry 328 of FIGS. 3, 5, and 6. In such examples, the bias circuitry 225, 310 ensures that the feedback circuitry 230, 312 is in an operational state responsive to biasing the control terminals of the transistors 334, 338.

The slew assist circuitry 240, 316 generates a slew assist current based on the differential inputs. (Block 735). In some examples, the slew assist circuitry 240, 316 generates a slew assist current through a first current path or a second current path. The first current path of the slew assist circuitry 240, 316 is controlled by the transistors 205, 302 and flows from the current source circuitry 235, 314 and through the transistors 366, 368. The second current path of the slew assist circuitry 240, 316 is controlled by the transistors 210, 304 and flows from the current source circuitry 235, 314 and through the transistors 370, 372. When a slew event occurs (e.g., a rising edge at one input and a falling edge at another input), the slew assist circuitry 240, 316 generates a slew assist current by turning on transistors of one of the first or second current paths and turning off transistors of the other one of the first or second current paths.

Also, when the first current path is active, the transistors 205, 302 also turn on the transistor 374 of FIGS. 3, 5, and 6 and when the second current path is active, the transistors 210, 304 turn on the transistor 376 of FIGS. 3, 5, and 6. In some examples, the transistors 374, 376 are sized relatively large in relation to the transistors 368, 372. In such examples, the transistors 374, 376 sink a current a multiple greater than any current through the transistors 368, 372. Such a sizing of the transistors 368, 372, 374, 376 reduces non-ideal currents from flowing through the transistors 368, 372 when turned off. In other examples, the transistors 374, 376 are coupled to the clamp circuitry 410, 510, 610 of FIGS. 4, 5, and 6, the resistors 520, 530, 635, 640 of FIGS. 5 and 6 generate voltages responsive to current from the transistors 374, 376 that fully disable the transistors 368, 372. In such examples, the clamp circuitry 410, 510, 610 uses currents from the transistors 368, 372 to further reduce non-ideal currents through the transistors 368, 372.

The feedback circuitry 230, 312 pulls down a control voltage. (Block 740). In some examples, the feedback circuitry 230, 312 uses the feedback current from the transistors 354, 360 to turn off one of the transistors 334, 338 and strongly turn on the other one of the transistors 334, 338. For example, when the transistors 205, 302 turn on the transistors 352, 354, the transistors 352, 354 supply the feedback current to the resistor 340, which generates a voltage that reverse biases and turns off the transistor 338. In such examples, when the transistors 210, 304 turn off the transistors 358, 360, the bias circuitry 225, 310 causes the transistor 334 to strongly conduct a current, which pulls down a control voltage at the control terminals of the transistors 346, 364.

The feedback circuitry 230, 312 and the current source circuitry 235, 314 determine if the control voltage is less than a threshold voltage. (Block 745). In some examples, one of the transistors 334, 338 pulls down the control voltage at the control terminals of the transistors 346, 364 responsive to slew operations of the feedback circuitry 230, 312. In such examples, the transistors 334, 338 increase currents being supplied to the feedback circuitry 230, 312 and the slew assist circuitry 240, 316. When feedback circuitry 230, 312 and the current source circuitry 235, 314 determine the control voltage is not less than the threshold voltage (e.g., Block 745 returns a result of NO), control proceeds to return to Block 745.

When feedback circuitry 230, 312 and the current source circuitry 235, 314 determine the control voltage is less than the threshold voltage (e.g., Block 745 returns a result of YES), the current source circuitry 235, 314 changes the slew assist current. (Block 750). In some examples, the transistor 364 is a p-channel field effect transistor structured to increase a supply of current to the slew assist circuitry 240, 316 as the gate-to-source voltage decreases. In such examples, the transistor 364 increases a supply of current to the slew assist circuitry 240, 316 responsive to the feedback circuitry 312 pulling down the control voltage at the control terminal of the transistor 364.

The current mirror circuitry 245, 318, 605 of FIGS. 2, 3, 4, 5, and 6 generates bias voltages based on the slew assist current. (Block 755). In some examples, the current mirror circuitry 245, 318, 605 uses the slew assist current from the transistors 368, 372 to generate a first bias voltage and a second bias voltage. In such examples, the first bias voltage is proportional to current through the transistors 366, 368 and the second bias voltage is proportional to current through the transistors 370, 372. For example, when the transistors 205, 302 turn on the transistors 366, 368, 374, the transistors 366, 368 supply the slew assist current to the transistors 378, 615 of FIGS. 3, 5, and 6, which set the first bias voltage proportional to the slew assist current. In such examples, when the transistors 210, 304 turn off the transistors 370, 372, 376, the transistors 370, 372 fail to supply current to the transistors 380, 625 of FIGS. 3, 5, and 6, which sets the second bias voltage approximately equal to the common potential. Also, when the transistors 205, 302 turn on the transistor 374 and the transistors 210, 304 turn off the transistors 370, 372, 376, the transistor 374 reduces non-ideal current through the transistor 372 by sinking a relatively large portion of the non-ideal current.

The output stage circuitry 110 changes a slew rate of an edge of the output signal using the bias voltages. (Block 760). In some examples, the power stage circuitry 120 mirrors the slew assist current responsive to receiving the bias voltages from the current mirror circuitry 245, 318, 605. In such examples, the transistor 135 changes a slew rate of rising edges of the output signal by sinking a replica of the current through the transistor 372 from the control terminal of the transistor 125 and the capacitor 130. Similarly, the transistors 160, 165, 170 change the slew rate of falling edges of the output signal by supplying a replica of the current through the transistor 368 to the control terminal of the transistor 150 and the capacitor 155.

The feedback circuitry 230, 312 and the slew assist circuitry 240, 316 determine if input currents of the differential inputs are approximately equal. (Block 765). In some examples, the feedback circuitry 230, 312 and the slew assist circuitry 240, 316 begin to approach steady state operations as currents from the transistors 205, 210, 302, 304 begin to settle after a slew event. If the feedback circuitry 230, 312 and the slew assist circuitry 240, 316 determine the input currents of the differential inputs are not approximately equal (e.g., Block 765 returns a result of NO), control proceeds to return to Block 765.

If the feedback circuitry 230, 312 and the slew assist circuitry 240, 316 determine the input currents of the differential inputs are approximately equal (e.g., Block 765 returns a result of YES), the feedback circuitry 230, 312 reduces the slew assist current. (Block 770). In some examples, when the feedback circuitry 230, 312 is in the steady state of operation, the current source circuitry 342 and the capacitor 344 pull up the control voltage at the control terminal of the transistor 364. In such examples, the feedback circuitry 230, 312 decreases the current supplied to the slew assist circuitry 240, 316.

The slew assist circuitry 240, 316 steers away excess slew assist current. (Block 775). In some examples, as further described above, the transistors 374, 376 are sized to be substantially larger than the transistors 368, 372 to reduce the excess non-ideal slew assist current from the transistors 366, 370 from being supplied to the current mirror circuitry 245, 318, 605. In some such examples, the clamp circuitry 410, 510, 610 further prevents the excess non-ideal slew assist current by clamping the slew assist circuitry 240, 316 to a voltage that fully disables the transistors 366, 370. Also, the clamp circuitry 410, 610 includes circuitry to directly sink the excess non-ideal slew assist current. For example, the transistors 645, 655 of FIG. 6 sink a current proportional to the current from the transistors 374, 376 (e.g., non-ideal currents). In such an example, the transistors 650, 660 of FIG. 6 sink replicas of the current through the transistors 645, 655 to further reduce non ideal currents from being supplied to the current mirror circuitry 245, 318, 605. Control proceeds to return to Block 705.

Although example methods are described with reference to the flowchart illustrated in FIG. 7, many other methods of implementing the input stage circuitry 105, 200, 300, 400, 500, 600 of FIGS. 1, 2, 3, 4, 5, and 6, or more generally the amplifier circuitry 100 of FIG. 1 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

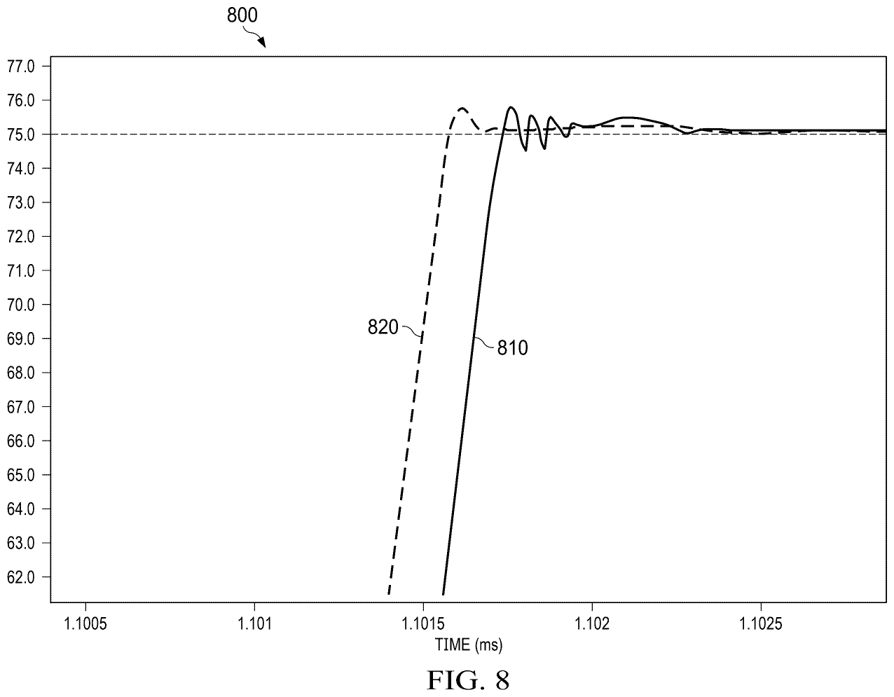

FIG. 8 is a timing diagram 800 of example operations of the amplifier circuitry 100 of FIG. 1. In the example of FIG. 8, the timing diagram 800 includes a signal increased path tail current 810 and a separate slew assist path boosted tail current 820. The signal increased path tail current 810 illustrates operations of amplifier circuitry that uses circuitry to increase the slew rate of an output by increasing currents of a signal path. For example, increasing a current of signals to the driver circuitry during slew events. The increased separate slew assist path tail current 820 illustrates operations of the amplifier circuitry 100, which uses the slew assist circuitry 240, 316 of FIGS. 2, 3, 4, 5, and 6 to generate separate signals to dynamically increase the slew rate of the power stage circuitry 120 of FIG. 1. Advantageously, the increased separate slew assist path tail current 820 settles faster than the signal increased path tail current 810.

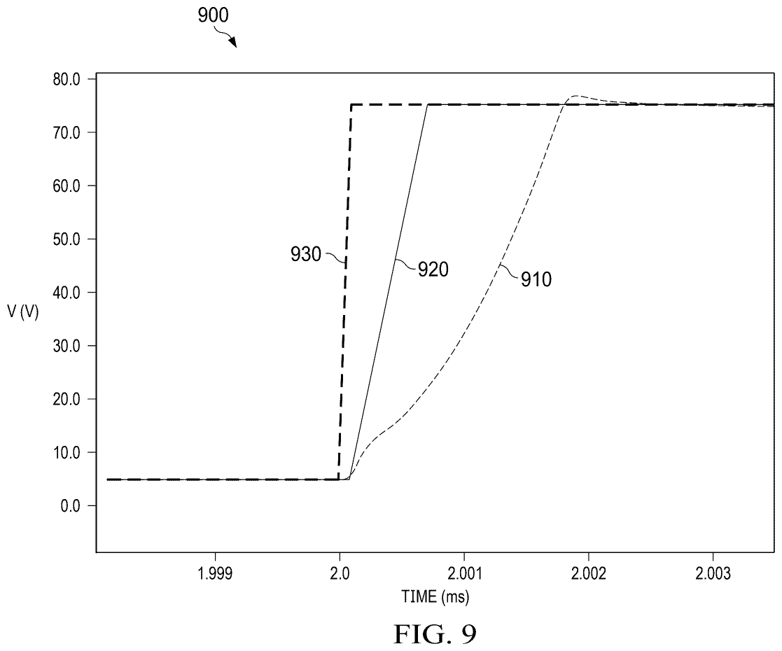

FIG. 9 is a timing diagram 900 of example operations of the amplifier circuitry 100 of FIG. 1. In the example of FIG. 9, the timing diagram 900 includes an increased signal path output signal 910, an increased separate slew assist path output signal 920, and an ideal output signal 930. The increased signal path output signal 910 illustrates operations of amplifier circuitry that uses circuitry to increase the slew rate of an output by increasing currents of a signal path. For example, increasing a current of signals to the driver circuitry during slew events. The increased separate slew assist path output signal 920 illustrates operations of the amplifier circuitry 100, which uses the slew assist circuitry 240, 316 of FIGS. 2, 3, 4, 5, and 6 to generate separate signals to dynamically increase the slew rate of the power stage circuitry 120 of FIG. 1. The ideal output signal 930 illustrates a target output signal having a nearly instantaneous transition from a first voltage to a second voltage. Advantageously, the increased slew assist path output signal 920 is capable of slew rates greater than the increased signal path output signal 910.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/-10 percent of the stated value, or, if the value is zero, a reasonable range of values around zero.

Modifications are possible in the described embodiments, and other embodiments are possible, within the scope of the claims.

What is claimed is:

1. An apparatus comprising:
a first transistor having a first terminal and a control terminal;
a second transistor having a first terminal and a control terminal, the first terminal of the second transistor coupled to the first terminal of the first transistor;
a third transistor having a first terminal and a control terminal;
a fourth transistor having a first terminal and a control terminal, the first terminal of the fourth transistor coupled to the first terminal of the third transistor;
feedback circuitry coupled to the first transistor, the second transistor, the third transistor and the fourth transistor;
current source circuitry having a first terminal and a second terminal, the first terminal of the current source circuitry coupled to the feedback circuitry;
slew assist circuitry coupled to the first transistor, the second transistor, the third transistor and the fourth transistor, the feedback circuitry and the current source circuitry; and
current mirror circuitry coupled to the slew assist circuitry.

2. The apparatus of claim 1, further comprising:
a fifth transistor having a first terminal and a control terminal, the first terminal of the fifth transistor is coupled to the control terminal of the first transistor, the control terminal of the second transistor, the feedback circuitry, and the slew assist circuitry; and
a sixth transistor having a first terminal and a control terminal, the first terminal of the sixth transistor is coupled to the control terminal of the third transistor, the control terminal of the fourth transistor, the feedback circuitry, and the slew assist circuitry, the control terminal of the sixth transistor is coupled to the feedback circuitry, slew assist circuitry, and the control terminal of the fifth transistor.

3. The apparatus of claim 1, wherein the slew assist circuitry includes:
a fifth transistor having a first terminal, a second terminal, and a control terminal;
a sixth transistor having a first terminal, a second terminal, and a control terminal, the first terminal of the sixth transistor is coupled to the current mirror circuitry;
a seventh transistor having a first terminal, a second terminal, and a control terminal, the first terminal of the seventh transistor is coupled to the current source circuitry and the first terminal of the fifth transistor;
an eighth transistor having a first terminal, a second terminal, and a control terminal, the first terminal of the eighth transistor is coupled to the current mirror circuitry;
a ninth transistor having a first terminal and a control terminal, the first terminal of the ninth transistor is coupled to the second terminal of the fifth transistor and the second terminal of the sixth transistor, the control terminal of the ninth transistor is coupled to the feedback circuitry, the control terminal of the seventh transistor, and the control terminal of the eighth transistor; and
a tenth transistor having a first terminal and a control terminal, the first terminal of the tenth transistor is coupled to the second terminal of the seventh transistor and the second terminal of the eighth transistor, the control terminal of the tenth transistor is coupled to the feedback circuitry, the control terminal of the fifth transistor, and the control terminal of the sixth transistor.

4. The apparatus of claim 1, wherein the slew assist circuitry further comprises;
a first resistor having a first terminal and a second terminal; and
a second resistor having a first terminal and a second terminal, the first terminal of the second resistor is coupled to the slew assist circuitry, the second terminal of the second resistor is coupled to the second terminal of the first resistor.

5. The apparatus of claim 1, wherein the current mirror circuitry includes;
a fifth transistor having a first terminal, a second terminal, and a control terminal, the first terminal of the fifth transistor is coupled to the slew assist circuitry and the control terminal of the fifth transistor; and
a sixth transistor having a first terminal, a second terminal, and a control terminal, the first terminal of the sixth transistor is coupled to the slew assist circuitry and the control terminal of the sixth transistor, the second terminal of the sixth transistor is coupled to the second terminal of the fifth transistor.

6. The apparatus of claim 1, wherein the slew assist circuitry further comprises clamp circuitry coupled to the slew assist circuitry and to the current mirror circuitry.

7. The apparatus of claim 1, wherein the second transistor further has a second terminal, the fourth transistor further has a second terminal, and the apparatus further comprising output stage circuitry including:
driver circuitry coupled to the second terminal of the second transistor and to the second terminal of the fourth transistor; and
power stage circuitry coupled to the current mirror circuitry and to the driver circuitry.

8. An apparatus comprising:
a first transistor having a first input;
a second transistor having a second input;
input transistor circuitry coupled to the first transistor and the second transistor, the input transistor circuitry having a first output and a second output;
slew assist circuitry coupled to the first transistor, the second transistor, and the input transistor circuitry, the slew assist circuitry having a first output and a second output; and
output stage circuitry coupled to the input transistor circuitry and slew assist circuitry, the output stage circuitry having an output wherein a slew rate of a voltage on the output is based on a voltage on the first output of the slew assist circuitry and a voltage on the second output of the slew assist circuitry.

9. The apparatus of claim 8, further comprising current mirror circuitry coupled to the slew assist circuitry and the output stage circuitry, the current mirror circuitry configured to:
mirror a first current of the first output of the slew assist circuitry;
mirror a second current of the second output of the slew assist circuitry; and
cause the output stage circuitry to increase the slew rate by supplying the first current and the second current.

10. The apparatus of claim 8, wherein the slew assist circuitry is further having a third output and a fourth output, and the apparatus further comprising:
a first resistor coupled to the slew assist circuitry; and
a second resistor coupled to the slew assist circuitry.

11. The apparatus of claim 8, further comprising clamp circuitry coupled to the slew assist circuitry, the clamp circuitry having a first output and a second output.

12. The apparatus of claim 8, further comprising:
current source circuitry coupled to the slew assist circuitry; and
feedback circuitry coupled to the first transistor, the second transistor, the input transistor circuitry, the slew assist circuitry, and the current source circuitry.

13. The apparatus of claim 12, further comprising current mirror circuitry coupled to the slew assist circuitry, the output stage circuitry, and the feedback circuitry.

14. The apparatus of claim 8, wherein the output stage circuitry includes:
driver circuitry coupled to the input transistor circuitry; and
power stage circuitry coupled to the slew assist circuitry and the driver circuitry.

15. An apparatus comprising:
feedback circuitry;
current source circuitry having a first terminal and a second terminal, the first terminal of the current source circuitry is coupled to the feedback circuitry;
a first transistor having a first terminal, a second terminal, and a control terminal;
a second transistor having a first terminal, a second terminal, and a control terminal;
a third transistor a first terminal, a second terminal, and a control terminal, the first terminal of the third transistor coupled to the current source circuitry and the first transistor;
a fourth transistor a first terminal, a second terminal, and a control terminal;
a fifth transistor having a first terminal and a control terminal, the first terminal of the fifth transistor coupled to the third transistor and the fourth transistor, the control terminal of the fifth transistor coupled to the feedback circuitry, the first transistor, and the second transistor;
a sixth transistor having a first terminal and a control terminal, the first terminal of the sixth transistor coupled to the first transistor and the second transistor, the control terminal of the sixth transistor coupled to the feedback circuitry, the third transistor, and the fourth transistor; and
current mirror circuitry coupled to the second transistor and the fourth transistor.

16. The apparatus of claim 15, wherein the current mirror circuitry includes:
a seventh transistor having a first terminal and a control terminal, the first terminal of the seventh transistor is coupled to the second transistor and the seventh transistor; and
an eighth transistor having a first terminal and a control terminal, the first terminal of the eighth transistor is coupled to the fourth transistor and the eighth transistor.

17. The apparatus of claim 16, wherein the current mirror circuitry further includes:
a ninth transistor having a first terminal and a control terminal, the control terminal of the ninth transistor is coupled to the second transistor, the seventh transistor, and the seventh transistor; and
a tenth transistor having a first terminal and a control terminal, the first terminal of the tenth transistor is coupled to the feedback circuitry and the ninth transistor, the control terminal of the tenth transistor is coupled to the fourth transistor, the eighth transistor, and the eighth transistor.

18. The apparatus of claim 15, further comprising:
a first resistor having a terminal coupled to the fifth transistor; and
a second resistor having a terminal coupled to the fifth transistor.

19. The apparatus of claim 15, further comprising input transistor circuitry coupled to the feedback circuitry, the first transistor, the second transistor, the fifth transistor, the third transistor, the fourth transistor, and the sixth transistor.

20. The apparatus of claim 19, further comprising output stage circuitry coupled to the input transistor circuitry and the current mirror circuitry.
